(19) United States
(12) Patent Application Publication
(10) Pub. No.: US 2024/0054260 A1
(43) Pub. Date: Feb. 15, 2024

(54) SYSTEM FOR BEHAVIOUR MONITORING

(71) Applicant: 4GD LIMITED, London (GB)

(72) Inventor: Robert Taylor, London (GB)

(21) Appl. No.: 18/274,169

(22) PCT Filed: Jan. 27, 2022
(86) PCT No.: PCT/GB2022/050219

§ 371 Date: Jul. 25, 2023

(30) Foreign Application Priority Data
Jan. 27, 2021 (GB) 2101084.8

(51) Int. Cl. G06F 30/20; G09B 9/00; G06F 3/01; G06T 11/00

(52) U.S. Cl. CPC G06F 30/20; G09B 9/003; G06F 3/013; G06T 11/00

(57) ABSTRACT

A system allows virtual and real events to take place contemporaneously and to influence each other. The system is configured such that an action by a real individual in the virtual environment causes the simulation of an event in real time for another real individual in a real environment, by the simulation apparatus; and an action by a real individual in the real environment causes the simulation of an event in real time in the virtual environment for the other real individual.

The invention is in the field of monitoring subject behaviour, such as the behaviour of human or animal subjects.

### BACKGROUND

There is a need for monitoring the behaviour of human or animal subjects in various environments including but not limited to training and gaming venues. It may be advantageous in such environments to collect data relating to behaviour and/or to provide automatic feedback, for example in the form of reactions or responses. This presents problems in terms of efficiently collecting the data and reliably providing the feedback.

In the case of training and gaming it is often desirable to simulate events in a manner that is as realistic as possible to provide an immersive experience for subjects. Some systems described in the following are designed to overcome some of the shortcomings of existing systems in providing a realistic user experience in an efficient, adaptable and cost effective manner.

Some embodiments of the invention described below solve some of these problems. However the invention is not limited to solutions to these problems and some embodiments of the invention solve other problems.

### SUMMARY

This summary is provided to introduce a selection of concepts in a simplified form that are further described below in the detailed description. This summary is not intended to identify key features or essential features of the claimed subject matter, nor is it intended to be used to determine the scope of the claimed subject matter.

There is described in the following a system for monitoring the behaviour of a human or animal subject. The system may comprise a plurality of subject sensors for monitoring the subject's behaviour including one or more body worn sensors; and a subject device to be worn by the subject and to receive sensor data from the body worn sensors. A variety of subject sensors may be provided including but not limited to eye tracking, biometric data sensing, weapon sensing and position sensing. Thus a rich set of data may be collected either for providing instant feedback and/or triggering of one or more events, or for later analysis, for example to monitor the performance of a subject, for example during a particular activity. In addition to the body worn sensors, one or more remote sensors may also be provided also for monitoring the behaviour of the subject, and these may also transmit data to the subject device. The system may have other applications such as initiating one or more events in a domain in response to the individual's behaviour.

A server may be arranged to receive sensor data from the subject device and to transmit instructions based on the subject sensor data. The system may further comprise a domain device to be located in the domain and to receive instructions from the server; and a plurality of domain actuators for causing one or more events in the domain in response to instructions from the domain device. The domain device may also be used to buffer or back up data collected by the subject device.

It should be noted here that the term “worn” is intended to encompass carrying unless otherwise stated, for example but not limited to carrying in a pocket. A body worn device may also be incorporated into clothing, worn on a harness or belt or other item of clothing. In any of the systems described here a device may be worn such that it does not require to be carried by hand albeit that it may in some instances be operated by hand. Other suitable devices may be configured to be operated completely hands-free.

There is also described in the following a system allowing virtual and real events to take place contemporaneously and to influence each other. The system may be configured such that an action by a real individual in the virtual environment causes the simulation of an event in real time for another real individual in a real environment, by the simulation apparatus. Also the system may be configured such that an action by a real individual in the real environment causes the simulation of an event in real time in the virtual environment for the other real individual.

Any of the systems for monitoring behaviour as described here may be used in a system allowing real and virtual contemporaneous events as described here. Other methods of implementing a system allowing real and virtual contemporaneous events, as described here, will become apparent to those skilled in the art.

There is also provided here there is provided here a target that may be provided with one or both of domain sensors and domain actuators, for example for use in simulation of military activities.

Features of different aspects and embodiments of the invention may be combined as appropriate, as would be apparent to a skilled person, and may be combined with any of the aspects of the invention.

### BRIEF DESCRIPTION OF THE DRAWINGS

Embodiments of the invention will be described, by way of example only and with reference to the following drawings, in which:

FIG. 1 is a schematic diagram of a system according to some embodiments of the invention;

FIG. 2 is a diagram similar to FIG. 2 including some specific examples of sensors and actuators that might be worn or carried by a person or installed in a domain according to some embodiments of the invention;

FIG. 3 is a diagram similar to FIG. 2 showing alternative examples of sensors and actuators according to some embodiments of the invention;

FIG. 4 is a flowchart showing the interaction between sensors and a subject device according to some embodiments of the invention;

FIGS. 5 to 7 are linked flowcharts showing how a subject device may interact with a server and subject sensors and actuators according to some embodiments of the invention;

FIGS. 8a, 8b, and 8c are linked flowcharts showing specific examples of sensors and events according to some embodiments of the invention;

FIG. 9 is a flowchart with specific examples of sensors and events according to some embodiments of the invention;

FIG. 10 is a perspective view of a subject in a domain using a system according to some embodiments of the invention;

FIG. 11 is a schematic illustration of a system comprising geographically separate domains according to some embodiments of the invention;

FIG. 12 is a schematic illustration of an alternative example of a system comprising geographically separate domains according to some embodiments of the invention;

FIG. 13 is a floor plan of a facility which may accommodate subjects respectively in real and virtual environments in the same building according to some embodiments of the invention;

FIG. 14 is a schematic diagram showing one example of how the real and virtual environments of the kind shown in FIG. 13 may be configured to represent a real life situation according to some embodiments of the invention;

FIG. 15 is an annotated aerial view showing how the combination of real and virtual environments may replicate a real environment according to some embodiments of the invention;

FIG. 16 is similar to FIG. 16 and additionally illustrates how the relative spacing and/or orientation of facilities in some systems may be different from their actual or physical spacing and orientation according to some embodiments of the invention;

FIGS. 17 (a) to (e) show examples of real and virtual targets that may be used in any of the embodiments of the invention;

FIG. 18 comprises schematic diagrams illustrating relationships between synthetic and virtual events which may be configured in any of the embodiments of the invention;

FIG. 19 shows schematically a synthesised view of the real environment such as might be visible to an individual in a virtual environment in any of the some embodiments of the invention;

FIGS. 20-22 are schematic diagrams showing systems similar to those of FIGS. 1-3 adapted to allow real and virtual events to take place contemporaneously and to influence each other.

Common reference numerals are used throughout the figures to indicate similar features.

### DETAILED DESCRIPTION

Embodiments of the present invention are described below by way of example only. These examples represent the best ways of putting the invention into practice that are currently known to the applicant although they are not the only ways in which this could be achieved.

As noted elsewhere herein, some embodiments of the invention provide a system for monitoring the behaviour of a subject, typically but not exclusively a human or animal subject. One or more events may then be initiated in a domain, for example where the subject is present, in response to the behaviour. In the following, from the perspective of a subject, the “domain” represents everything outside the subject and may include other humans or animals.

Additionally or alternatively to the initiation of events, the system may be used to collect data from subject devices that may be used either in real time or for later analysis, for example to provide feedback to the subject, and/or to analyse some aspect of the performance of the subject over a period of time.

In any of systems described here the domain may comprise only inanimate and optionally fixed structures. For example the domain may comprise a dedicated training or games facility equipped to provide as near as possible a simulation of a real life environment, using physical real effects as much as possible, described further in the following. In some systems described here the domain may also comprise other users of the system, usually other humans, generally referred to here as “individuals”.

Systems and methods as described here may create real or virtual events or both. Real events may be simulated. In the following, unless otherwise stated, “real” is used to mean actually existing, or genuine; “virtual” is used to mean computer-generated, for example but not necessarily three dimensional; “synthetic” has the same meaning as “virtual”, and “simulate” is used to mean imitate. Notably real objects and events may be simulated either virtually or using real objects or effects, or a combination of real and virtual, as will be described further below. Simulation may comprise causing a safe form of a real event, such as causing a small safe explosion to simulate a real explosion. Therefore simulated events are also real.

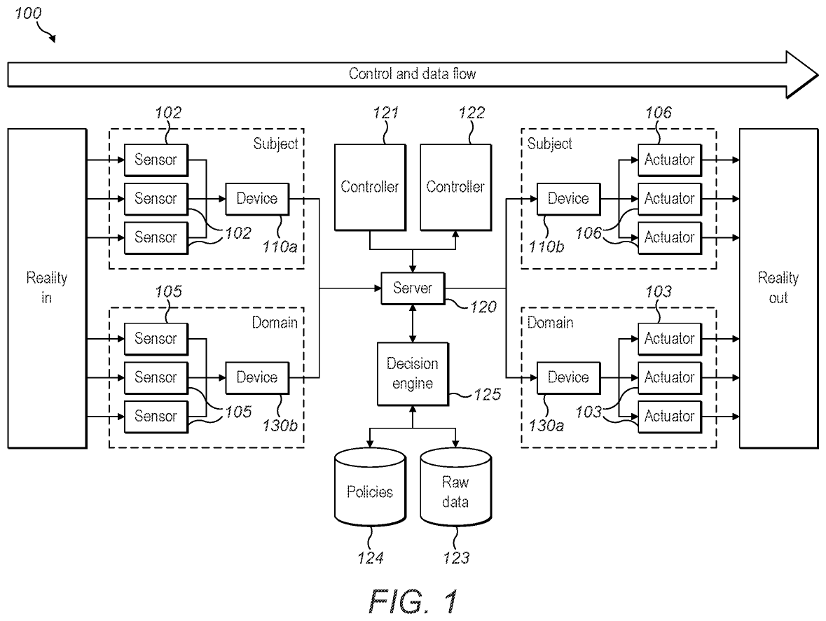

FIG. 1 shows an example of one such system 100. The system of FIG. 1 generally comprises a plurality of subject sensors 102 for monitoring the behaviour of a subject, e.g. person (not shown in FIG. 1). The subject sensors 102 include one or more body worn or carried sensors, and optionally in addition one or more remote sensors. References to body worn sensors in the following are intended to include sensors carried by a subject unless otherwise stated. Examples of body worn sensors, include but are not limited to a heart rate monitor, movement sensor, and so on. Thus it will be clear that the term “behaviour” as used here is not limited to deliberate behaviour on the part of the subject and includes for example physiological and involuntary behaviour. Examples of remote sensors include but are not limited to surveillance cameras and movement sensors.

The system further comprises a subject device 110a to be worn by the subject and to receive sensor data from the body worn sensors and from the remote sensors, and a server 120 arranged to receive sensor data from the subject device 110a and to transmit instructions based on the subject sensor 102 data. In some applications for systems as described here it may be important to collect subject data, i.e. data from subject sensors, in a manner that minimises any loss of or corruption of the data. This is one reason for the subject sensors 102 transmitting their signals or data to a subject device 110a worn on the body. For example this removes the possibility of data being lost or corrupted or delayed due to wireless black spots in a building or other in homogeneities in the transmission environment. For some of the applications described here it is desirable to collect data with a high degree of granularity and this is an additional benefit of the sensor data being collected on a body-worn device.

The system 100 may further comprise a domain device 130a to be located in the domain and to receive instructions from the server 120, and a plurality of domain actuators 103 for causing one or more events in the domain in response to instructions from the domain device 130a. The instructions from the server 120 may be based on data received from one or more of the subject sensors so that, for example, something happens in response to an action or other behaviour of a subject. Examples of events are described further below.

It will be appreciated from the foregoing that in some systems described here the subject device is able to receive sensor data not only from sensors worn by the subject but also from sensors in the domain that are remote to the subject, and that both kinds of information may be used in deciding whether and what kind of event to cause in response to the sensor data. However this is not a requirement of the systems described here and some may comprise only body worn subject sensors.

By feeding data from remote sensors, optionally also from the body worn sensors, to the body worn subject device, sensor data relating to the behaviour of the subject is routed more efficiently to the server from which a decision may be made as to whether an event should be caused.

Some examples of subject sensor data, optionally leading to a domain actuator being actuated, include but are not limited to:

In a simulated military environment, a subject sensor could be an eye movement tracker, for example incorporated in a subject headset. A number of eye movement trackers are commercially available, for example details may be seen at pupil-labs.com. Among other things these are able to determine the direction of the gaze of a subject. This may be used to provide a real-time response or to gain insights into the behaviour of the subject. As an example of a response or event, a domain actuator could comprise a speaker. Then the sensing of particular eye movements could lead to a sound being played to a subject, for example the subject's gaze being directed at an unarmed “target” could lead to aggressive, e.g. vocal, sounds being played. It should be noted here that a subject headset including eye movement tracking and other functions is known in military and other equipment and is distinct from a virtual reality headset mentioned elsewhere here.

Subject sensors could include biometric devices of any kind. Some are able to detect the subject's stress level, in ways well known in the art. Again this could either be stored for later analysis or to provide a real time response. For example, if the stress level of a subject increased beyond a threshold an event could take place such as a change in the course of simulated activity aimed at reducing the subject's stress level. The simulated activity may be generated at least in part by domain actuators.

Other examples of subject sensors may comprise sensors on equipment carried by a subject, such as a weapon sensor. A suitable such subject sensor may be able to detect the subject's last round of ammunition being used which could for example trigger a domain actuator playing a sound such as a shout “he is out of ammo”. Other kinds of weapon sensor known in the art include direction pointing sensors and/or other sensors determining the accuracy of firing a weapon. Notably here this kind of system is not limited to training or gaming environments and may be applicable to real life situations. For example a weapon as mentioned here could include a lethal weapon as well as a non-lethal weapon.

Any of the foregoing, and other examples of subject sensing and optionally domain activation, may be used in any combination.

FIG. 1 shows an example system for one subject in one domain but it will be appreciated that the system could be extended to include sensors and subject devices for multiple subjects and optionally also actuators and domain devices for multiple domains. Thus for example a system as shown in FIG. 1 could be extended to be used by a single subject in multiple domains or multiple subjects in a single domain or any number of subjects and domains.

It will be appreciated that any of the sensors 102 that are to be body worn may be comprised in the subject device which itself is to be worn by the subject. More usually one or more subject sensors are separate from the subject device in that they are arranged to transmit data, e.g. sensor signals, to the subject device, via one of various possible kinds of communication channel as described further below.

The system shown in FIG. 1 further comprises a plurality of domain sensors 105 arranged to detect one or more events in the domain. The term “domain sensor” is used here to denote sensors which sense data without reference to the subject. In the systems described with reference to the figures, the domain sensors 105 do not supply sensor data to the subject device 110a,b.

The server 120 shown in the figures is arranged to receive sensor data from the domain sensors 105 and to transmit instructions based on the domain sensors 105 data to at least the subject device 110b. Further, a plurality of subject actuators 106 is provided for causing one or more events at the subject in response to instructions from the server 120. Thus, for example, something can be caused to happen to the subject in response to something sensed in the domain. The subject actuators may be worn on the body and at least some subject actuators may be comprised in the subject device.

As shown in FIG. 1 the subject actuators 106 may be arranged to receive instructions from the server 120 via the subject actuator, indicated as 110b. Thus items 110a and 110b in FIG. 1 represent the same subject device.

As shown in FIG. 1, the domain sensors 105 are arranged to transmit their sensor data to the domain device, indicated as 130b, which then transmits the domain sensor 105 data to the server 120. Thus, items 130a and 130b in FIG. 1 represent the same domain device.

In a simulated environment, the provision of the domain sensors 105 and subject actuators 106 may be used to create a more realistic experience for the subject or other users discussed further below, where not only does the domain respond to the subject via the domain actuators but also the subject may experience events based on domain sensor data.

From the viewpoint of one subject, the “domain” may comprise everything outside the subject. Other humans or animals may be active in the domain and may generate data sensed by the domain sensors 105 which may then be used to cause an event at the subject.

To summarise the functions of the sensors and actuators in use:
A subject sensor is arranged to monitor the behaviour of a subject and may be worn on the body or remote from the subject.
A subject actuator is worn on the subject's body and functions to cause an event at the subject.
A domain sensor is not worn by the subject and senses data without reference to the subject.
A domain actuator is not worn by the subject and causes an event which may or may not affect the subject.

Some examples of sensed data and events are described further below. It should be noted that for some sensors, the same kind of sensor may be used as a subject sensor or a domain sensor. One example of such a sensor is a camera which may be configured, e.g. through the use of image processing and suitable programming, to report data relating to the subject's behaviour to the subject device 110a and to report other image data to the domain device 130b.

Additional actuators and sensors may be provided which communicate directly with the server.

It can be seen in FIG. 1 that the system comprises multiple sensors for a subject and domain respectively sensing reality, noted in FIG. 1 as “Reality In”, and multiple actuators for the subject and domain respectively for causing real events, noted in FIG. 1 as “Reality Out”. Control and data flow is from the subject and domain sensors to the subject and domain actuators, to and from the subject and domain devices 110a,b; 130a,b via the server 120.

Any of the subject and domain devices 110a,b; 130a,b and the server 120 may comprise computing devices comprising one or more processors and memory as is known in the art, and may be configured to perform operations described here through suitably programming the one or more processors. Any suitable computing devices may be used as will be familiar to those skilled in the art. Wearable devices may for example comprise personal communication devices such as but not limited to smart phones or tablet computing devices or dedicated devices for use in a facility in which a system is installed. Instead of comprising a commonly available or generic device, any of the devices described here, particularly the subject device, may comprise a dedicated device designed for the particular purposes described here. For example it may comprise an off the shelf device customised with suitable software and/or with suitable hardware or may be entirely designed for the desired purpose.

The subject device 110a,b may be configured to communicate directly with at least one of the subject actuators 103 to transmit instructions based on the subject sensor 102 data. For example it may be configured to determine whether instructions are to be prioritised and hence transmitted from the subject device, for example according to one or more rules configured on the subject device, and if so to transmit instructions from the subject device directly to one or more subject actuators. Similarly the domain device 130a,b may be configured to communicate directly with at least one of the domain actuators 103 to transmit instructions based on the domain sensor 105 data.

The system 100 overall may be configured to implement a set of rules, also known as policies, based on sensor 102, 105 data. One or both of the domain device 130a,b and the subject device 110a,b may be configured to implement at least one of the rules independently of the server 120, for example by having its own raw data and policies stores and associated decision engine.

The server 120 in FIG. 1 is shown to communicate with a controller 121 and display 122. The controller may be another computing device which may be used to configure or otherwise control the server 120, and from which output information from the server 120 may be viewed. Thus the controller may comprise a user interface such as a touch screen. Alternatively one or more separate user interface devices may be provided such as mouse, keyboard, etc. The display 122 may be provided as an alternative means of viewing output information, for example if a display is not comprised in the controller 120. The server 120 communicates with or comprises raw data store 123 and policy store 124 via a decision 125 engine. The raw data store may retain the sensor data and the decision engine may be configured to implement the policies or rules based on the sensor data.

In order for the domain device 130a,b and/or the subject device 110a,b to implement a rule independently of the server 120, one or both of them may be configured to process sensor data to determine whether to cause an event or to transmit the data to the server 120 for the server to determine whether to cause an event. For example, certain sensor data or combinations of data from different sensors may require instantaneous feedback to a subject in order to be valuable, in which case it may be processed and responded to at a subject or domain device instead of being routed to the server. Suppose for example that a subject in a training or gaming environment is virtually injured and may no longer participate, a system may be configured such that this is communicated to the subject instantaneously, in which case the event may be a sensation felt by the subject or an audible “you're dead” message. In this example, subject sensor sensing the injury of the subject could be a biometric device that correlates different measures and infers pain, or a special body suit that detects the impact of a bullet, and the subject actuator may be a haptic feedback device or a headset. More generally, the rules may prioritise certain events according to certain sensor data or combinations of sensor data, and the determination may then be according to the priority of the required event. This ensures that certain events occur when they are required, without latency that might be present if the decision is made by the server 120. Also, the use of computing power at the devices and the server may be optimised according to event priorities.

Therefore according to some embodiments of the invention, any of the domain devices may comprise a policy store and a decision engine, some of which may partially duplicate the policy store and decision engine at the server.

A system according to some embodiments may be configured for the subject to be outside the domain. In other words while the domain may comprise everything external to the subject, a domain may be defined so that the subject is not present within it. Thus for example the behaviour of a subject in one domain may cause an event in another domain. Other subjects may be present in the other domain. This opens up the possibility of interactive activities taking place between subjects in different locations.

It should be noted that systems according to embodiments of the invention may be configured such that the collection of data from the sensors is entirely passive, in other words no action is required on the part of the subject, or an operator of a domain, to enable the collection of the data.

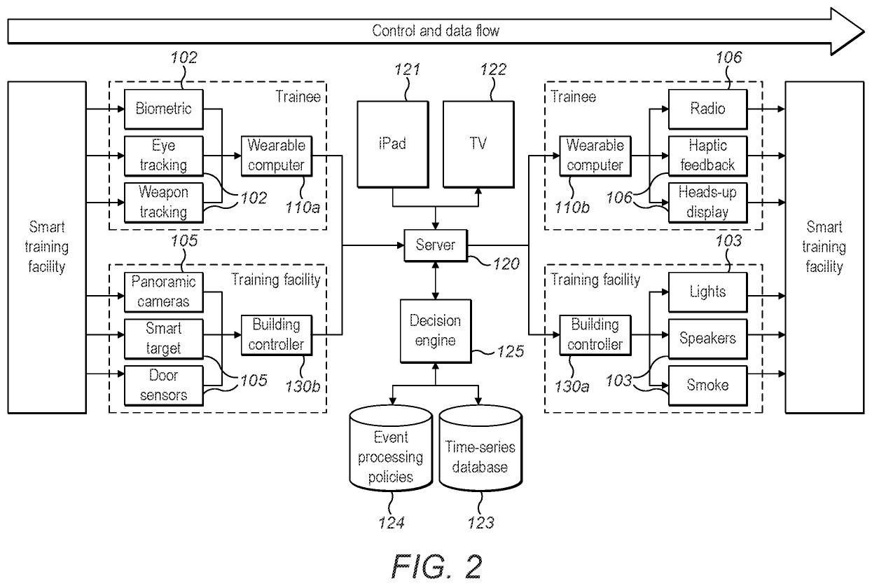

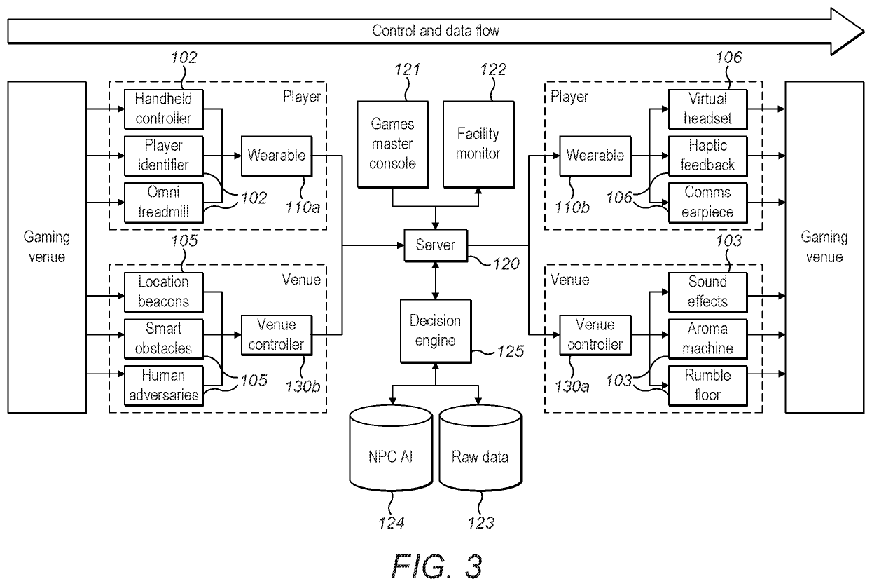

Systems described here may be implemented in a variety of environments as previously noted. Two such environments will be described with reference to FIGS. 2 and 3. Any of the features of either of these examples may be implemented in the other and neither should be considered to be a closed system.

FIG. 2 shows schematically how the system of FIG. 1 might be used in a smart training facility which may be used for example to train subjects to behave in a manner appropriate to a simulated environment. Thus in FIG. 2 the “reality” of FIG. 1 comes from (reality in) or is provided to (reality out) the smart training facility.

Here the subject sensors 102 are shown at the top left of FIG. 2 to comprise one or more biometric sensors, eye tracking sensors for example to track eye movements, and one or more weapon tracking sensors for monitoring the use of a weapon by the subject. All of these example sensors may be wearable. Some such may be provided on equipment carried by the subject, as the weapon tracking sensor. Another particularly useful subject sensor, not shown in the figures, is a positioning sensor.

A variety of biometric sensors will be known to those skilled in the art and any such sensors may be used as subject devices in the systems described here. A suitable example is available from Bodytrak® and is an in-ear device capable of monitoring various key vital sign parameters. Single-parameter devices such as but not limited to heart-rate monitors may be used.

Similarly a variety of weapon tracking sensors may be used which are able to sense various parameters relating to the use of a weapon. Suitable examples are described at armaments.us.

Position sensing may use any known technology. A suitable option based on ultra wide band (UWB) technology and solutions for indoor and outdoor use are described at pozyx.io.

A system comprising subject sensors communicating with a subject device is capable of providing a wealth of information relating to the behaviour of a subject for either real time feedback or later analysis. The sensor combination of eye tracking and weapon tracking is particularly beneficial, and this in combination with biometric sensing and optionally position sensing greatly enhances the ability to gain insights into the behaviour, including performance, of a subject. This is particularly useful in training for urban dismounted close combat.

Whilst systems for monitoring health related parameters are known, for example using smart phones, they are generally not configured in the manner described here where data from multiple sensors is collected at a subject device, optionally at a high level of granularity, for later analysis. Systems are known for monitoring various signs of a patient in a hospital but these do not generally monitor the patient carrying out activities and do not generally include a wearable device. Some of the systems described here are aimed at the particular problems of obtaining data relating to the behaviour of a subject at a high level of granularity and accuracy whilst not restricting the activity fo the subject.

Additional subject sensors may not be worn by the subject and may comprise movement sensors to sense movement in the domain and/or cameras. Any other wearable or non-wearable sensor for monitoring the behaviour of a subject may be included in any of the systems described here. The subject device is shown to be a wearable computer, duplicated on the right and left of FIG. 2 and indicated as 110a, 110b.

The domain actuators on the right of FIG. 2 are shown to comprise lights, speakers, and a smoke generator. Thus events that may be caused in the domain include switching on of lighting, generation of sound via the speakers and generation of smoke. These are a few examples of domain actuators and events that may be caused. Systems described here may comprise other domain actuators for causing other events. The domain device is shown to be a building controller, duplicated on the right and left of FIG. 2, it being noted that the domain may be a whole building or one of several rooms in a building each of which is a domain in the system controlled by the same building controller.

The domain sensors on the left of FIG. 2 are shown to comprise panoramic cameras, a smart target to be described further below, and door sensors. From this it will be appreciated that some sensors may function as both domain sensors and subject sensors. Thus, for example, a sensor could communicate with both a subject device and a domain device for the sensor data to be treated as domain sensor data or subject sensor data or both.

In another aspect there is provided here a target that may be provided with one or both of domain sensors and domain actuators, for example to make it “smart”. The target described here is not limited to use in the systems described here and may have other applications. An example of a “smart” target provided here could be an object provided with sensors including one or more of a) a microphone to sense audio disturbance above a dB level, b) a camera to detect motion, and actuators including one or more of c) the ability to rotate, d) the ability to fire back, e) play audio (e.g. shouting) and f) “drop” vertically downwards when dead. Thus a smart target could be included on the right in FIG. 2 as a domain actuator. Other sensors and actuators may be provided in a target. Thus some of the sensors in the target may communicate with a subject device to transmit information relating to the subject behaviour in addition to or alternative to communicating with a domain device.

The subject actuators on the right of FIG. 2 are shown to comprise a radio, haptic feedback device and heads-up display. The actuators may be used in various ways including but not limited to the following examples. A radio might play an audio voice message to the subject simulating another subject such as “who fired?” when the subject fires a weapon. A haptic feedback device could be used so that if a subject is “shot” they are “shocked” to show them that they have been hit. Notably haptic “suits” are now available so that a subject can feel the effect of a shot at various parts of the body. A heads up display could be used to display to a subject the number of rounds of ammunition remaining, sensed by a subject sensor. These are all examples of ways in which subject sensor data may be used to cause events.

The server is shown to be connected to a tablet computing device which may serve as a controller for the server in a similar manner to the controller 121. A display 122 such as a TV screen may also be provided.

The policies stored in policies database 124 are shown in FIG. 2 to be event processing policies and the raw data store 123 is shown to comprise a time series database.

FIG. 3 shows schematically how the system of FIG. 1 might be used in a gaming venue. One example of a gaming venue is a so-called “escape room”. Other examples will be familiar to those skilled in the art. So in FIG. 3 the “reality” comes from or is provided to the gaming venue.

In the system of FIG. 3 the subject sensors are shown on the left to comprise a handheld controller which may be wearable, a player identifier which may be wearable, and an omni-directional treadmill Whether or not the subject sensors are wearable, they communicate with the subject device which is wearable. The domain sensors are shown to comprise location beacons, smart obstacles and human adversaries. The beacons would be picking up a player's exact location in space, the smart obstacles might be doors or walls that can detect being opened or collisions, and human adversaries may be an “opposing force” that are not players, optionally clothed in the same way as a subject, but making up part of the game in some other way (e.g. getting in the way). The domain device is shown to be a venue controller.

The subject actuators are shown on the right of FIG. 3 to comprise a virtual headset, a haptic feedback device and a communications earpiece. These may be used in various ways, for example if a simulation is caused in a game, such as an explosion, then the outputs would be felt in these devices (Headset: Visual, Communications Earpiece: Audio and Haptic Device: Physical). The domain actuators are shown to comprise a sound effects generator, an aroma machine and a rumble floor.

The controller in the system of FIG. 3 may comprise a games master console which may perform similar functions to the controllers mentioned in connection with FIGS. 1 and 2. The display 122 of FIG. 1 may take the form of a facility, e.g. gaming venue, monitor in the system of FIG. 3.

The policies stored in policies database 124 are shown in FIG. 3 to be a non-playing automated character using artificial intelligence (NPC AI) as is known in the field of gaming.

The systems described here may be configured to incorporate various kinds of sensor and actuator and do not require them to be designed for compatibility with other components of the system. Methods in which data may be managed will now be described.

It will be appreciated from the foregoing that the subject (also referred to here as individual) sensors in any of the systems described here may comprise but are not limited to any one or more of: eye movement tracking, biometric sensors, sensors provided on subject equipment, position sensing, cameras and other surveillance devices, microphones, handheld controllers, player identifiers, treadmills and other sensors capable of sensing subject activity or behaviour.

The domain (also referred to here as environment) sensors in any of the systems described here may comprise but are not limited to any one or more of: cameras, sensors to detect movement of doors and other moveables, targets, location beacons and human adversaries provided with sensing equipment.

The subject actuators in any of the systems described here may comprise but are not limited to any one or more of: speakers e.g. in earpieces, haptic feedback devices, heads-up displays.

The domain actuators in any of the systems described here may comprise but are not limited to any one or more of: lighting, speakers, smoke generators, aroma generators, reactive targets, vibration devices such as rumble flooring, heating, air conditioning.

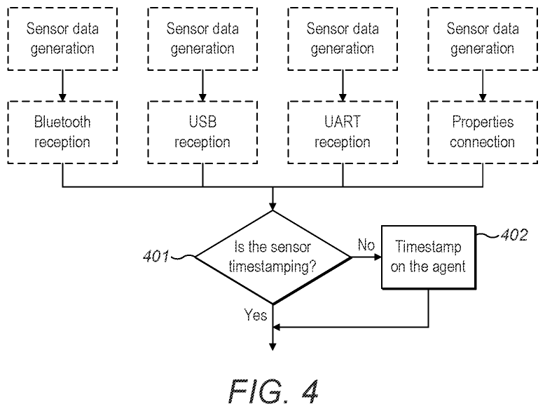

FIG. 4 is a flowchart showing the interaction between sensors 102 and a subject device 110a,b according to some embodiments of the invention. FIG. 4 shows schematically that different sensors, may communicate in various ways with the subject device 110a,b. In FIG. 4 and the other flowcharts to be described below, the operations of sensors or actuators are shown in dotted lines, the operations of devices are shown in solid lines and the operations of the server are shown by broken shapes. However it will be appreciated that some operations may in alternative embodiments be performed in a sensor or actuator rather than a device, and vice versa.

FIG. 4 shows that a system may be configured to receive data from different sensors in different ways including but not limited to short range wireless communication such as Bluetooth and near field communication “NFC”, universal serial bus “USB” which may be wired or wireless, Universal Asynchronous Receiver/Transmitter “UART” or some other proprietary connection.

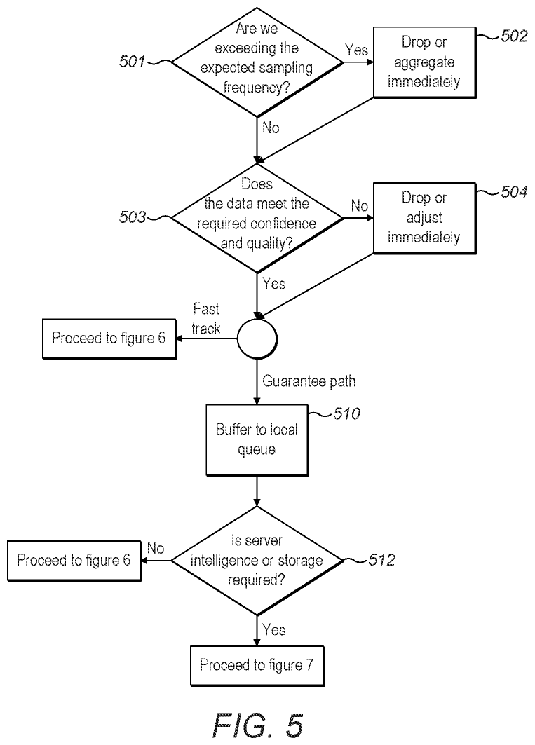

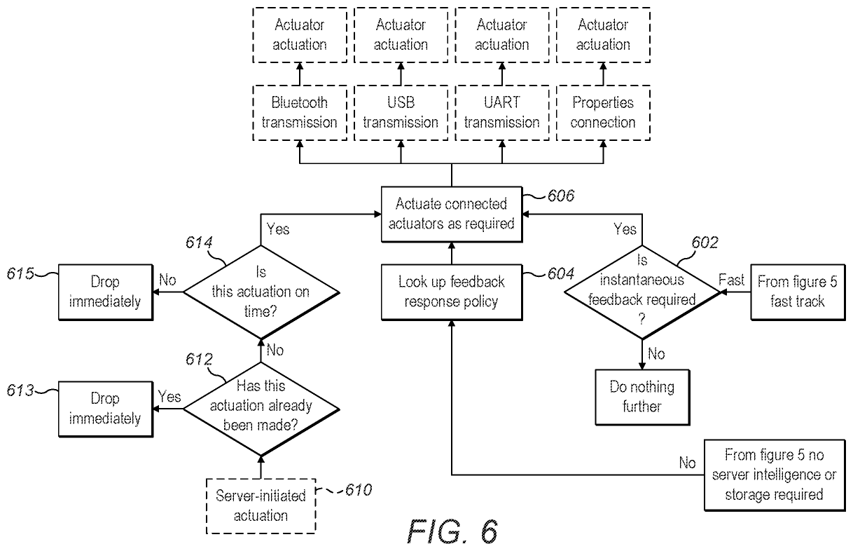

Some systems described here may require data to be timestamped. Therefore a first decision by the device may be to determine whether the data is timestamped by the sensor, as indicated by operation 401, and if not to timestamp the data at operation 402, after which the flow continues to the operations shown in FIG. 5.

An analogous flow to that shown in FIG. 4 may be implemented in a domain device. In other words, in some embodiments, a domain device may be capable of sensing and actuation independent of the server. For example, a speaker may be used by a domain device to play background sounds along a timeline, which may be in response to one or more sensor signals and which is configured once onto the domain device and does not require further server interaction. In another example a sensor may comprise a LIDAR device that detects one or more objects in the facility. A system could be configured such that signals from this device were communicated to the domain device and the domain device might instruct one or more domain actuators in response to cause one or more events in the domain.

FIG. 5 shows a data flow for data from one sensor. A parallel flow may take place for each sensor from which a device is receiving data. In FIG. 5 the frequency and confidence level in the received data are examined.

At operation 501 a determination is made whether the sensor data is exceeding an expected or threshold sampling frequency. If so, the amount of data is reduced at operation 502, either by dropping some of the data or aggregating the data to arrive at a frequency below the threshold.

More generally, one or both of the subject device and the domain device may be configured to record sensor data from multiple sensors, wherein data is received from different sensors at different rates and the device is configured to record different proportions of data from different sensors.

The flow then continues to operation 503 where it is determined whether the data meets required standards for confidence and quality. If it does the flow continues. If not, at operation 504 the data is either dropped, or adjusted in which case the flow continues. An example of adjustment of data is the application of a known “standard error” which can be applied by a device before the flow continues. Other kinds of correction will be familiar to those skilled in the art.

One or both of the subject and device sensors may be configured to record sensor data according to the level of confidence in the data accuracy. Optionally, one or both of the subject and device sensors may be configured to determine or improve the level of accuracy of data from one sensor based on data from another sensor. An example is where a magnetometer (for compass direction) is augmented using an accelerometer (for dead reckoning) to get a true bearing. Other examples that use one sensor to determine or improve the accuracy of information from another will be familiar to those skilled in the art.

Some sensor data is handled via a “fast track”, for example according to the priority of an event required to be caused, in which case the flow continues to FIG. 6.

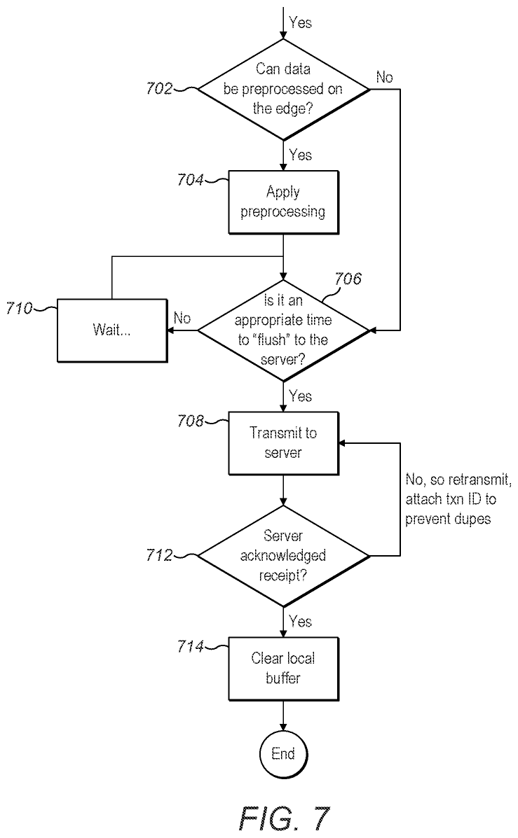

Whether or not data is fast tracked, it may be handled via a guarantee path, i.e. a path of logic that ensures the data is not lost, commencing with the data being buffered to a local queue at operation 510 and then subject to a decision whether server intelligence or storage is required at decision 512. The guarantee path may operate in parallel with the fast track where the fast track flow of FIG. 6 operates. If server intelligence or storage is required, the flow continues to the operations shown in FIG. 7. Otherwise the flow continues to operations shown in FIG. 6.

In FIG. 6, the first operation in the fast track flow is a decision whether instantaneous feedback is required at operation 602. If no, nothing further is done at the device but the data is handled according to the flow shown in FIG. 7 in which the data is transmitted to the server and the server may initiate an event. In parallel with this decision making, if it was determined in FIG. 5 operation 512 that no additional server intelligence was required, at operation 604 in FIG. 6 a feedback response policy, for example stored in a policy database at the subject device 110a,b is consulted for the policy to be applied, e.g. event to be caused, according to the received sensor data. At operation 606, one or more appropriate subject actuators 106 is actuated, the actuators 106 and their connections to the subject device 110a,b being indicated in dotted boxes in FIG. 6. Similarly to the subject sensors 102 described with reference to FIG. 4, the subject actuators 106 may be connected to the subject device in a variety of ways.

The operations on the left in FIG. 6 show how an event may be caused at the subject in response to instructions from the server. The server may transmit instructions for such events to be caused based on subject sensor 102 data, domain sensor 105 data, or both. At operation 610 the server 120 transmits an instruction to the subject device 110a,b to initiate an event such as the actuation of one of the subject actuators 106. Prior to acting on the instruction some decisions may be made at the subject device, such as “has the actuation already been made?” at decision 612, or “is the actuation on time?” at decision 614. One reason for providing these decisions is to minimise synchronisation or latency errors between the device and the server. For example referring to decision 612, it is possible that the instruction was received previously and acted on by the device, but an interrupt in connectivity delayed or prevented the device confirming this to the server. If the event has already been caused the instruction is dropped at operation 613. Referring to decision 614, it is possible that the instruction was delayed such that causing the event would now be meaningless, for example because of the progress of activity in the domain. If the event, or actuation, would not be “on time” according to decision 614, the instruction is dropped at operation 615.

If the instruction from the server was not already acted on and is on time, the flow continues to operation 606 where one or more appropriate subject actuators 106 is actuated.

FIGS. 4-6 show how a subject device may interact with a server to cause operation of the subject actuators in response to signals from the subject sensors.

A subject device may similarly interact with the server to cause operation of the domain actuators in response to signals from the subject sensors, with the domain actuators being instructed by the domain device. The flow implemented in the domain device could be similar to operations 610, 612, 614 and 606 in FIG. 6, with the domain device receiving an instruction from the server to cause an event and optionally checking whether the event has been caused already or is out of time. At operation 606 the domain device 103a,b would actuate connected domain sensors 103 as required.

The data may be handled according to the flow of FIG. 7 whether or not the fast track flow of FIG. 6 was implemented. Here, all sensor data is reported to the server for long term storage.

Recall that the flow of FIG. 7 follows decision 512 according to which server intelligence or storage is required. The operations of FIG. 7 may take place at a subject device 110a,b or a domain device 130a,b. At operation 702 a decision is made whether the sensor data can be pre-processed at the “edge”, e.g. at the device 110a,b or 130a,b. Non-limiting examples of pre-processing include aggregation, e.g. aggregation of heart rates into a time window e.g. from 1 ms sampling to a 100 ms aggregation, the aforementioned fusion of magnetometer and accelerometer to get a true bearing, and inferring of a higher-order event (e.g. a shot detection) from lower-order data (e.g. accelerometer and audio data from a weapon sensor) without having to use server logic and thereby optionally saving on processing requirement at the server. If yes this is done at operation 704 and the flow continues to decision 706, or if no the pre-processing is bypassed and the flow proceeds to decision 706. Decision 706 is whether the time is right to flush data from the device to the server, in which case data is either transmitted to immediately the server at operation 708 or after a wait at operation 710. Criteria for whether the time is right might include a threshold amount of data or a time boundary (e.g. every half second).

In operations 708, 712 and 714, the data stored at the device that is to be flushed is either retransmitted if no acknowledgement is received from the server or cleared from the local buffer, e.g. device storage.

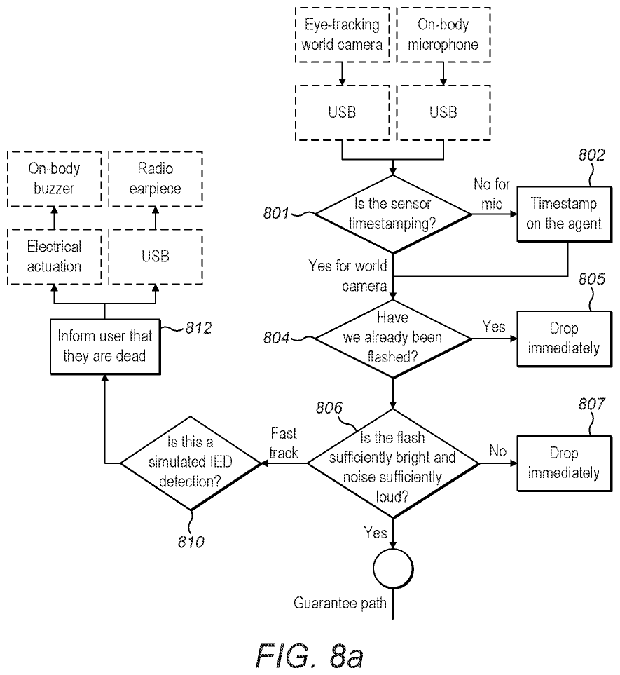

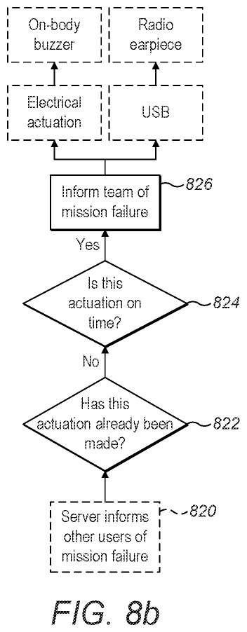

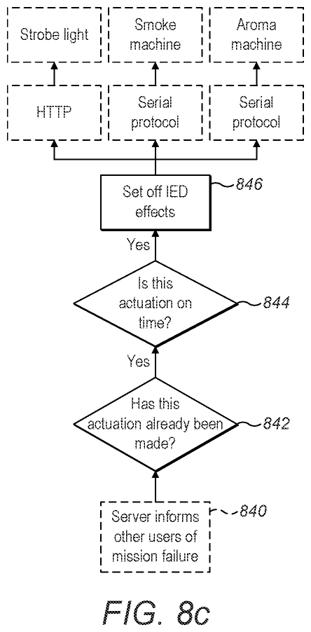

FIGS. 8a, 8b, and 8c are linked flowcharts similar to those shown in FIGS. 4-7 with specific examples of sensors and events according to some embodiments of the invention. This example flow is to determine whether an improvised explosive device “IED” explosion has been simulated and if so to cause one or more events at a subject. The IED explosion simulation may have been implemented using one or more domain actuators in response to subject sensor signals, such as the subject entering a particular area within the domain. The flows are similar to those described with reference to FIGS. 4-7 with the following additional or alternative details:

FIG. 8a shows two example subject sensors, an eye-tracking world (outward facing) camera such as might be provided as part of headset, and an on-body microphone, both communicating with the subject device 110a, 110b, via a USB connection. As with the flow of FIG. 4, a check is made at 801 as to whether the data has a timestamp and if not a timestamp is applied at the device at 802. FIG. 8a shows that the camera timestamps the data it sends but the microphone does not.

At 804 a decision is made whether sensor data has already been received indicating a “flash” from an explosion (meaning sound and bright light) in which case there is no need for additional data to be stored and it is dropped at operation 805. At 806, if a flash was not already detected it is determined whether the sensor data indicates a sufficiently bright light and sufficiently loud noise, and if not the data is also dropped at 807.

The sensor data may then be processed in parallel fast track and guarantee paths. The guarantee path may comprise similar steps to operations 510, 512 and FIG. 7. The pre-processing at operation 704 might comprise the creation of an IED “event” to be transmitted to the server.

The fast track flow of FIG. 8a comprises a further check at 810 to ascertain that an IED explosion was detected, in which case an instruction is issued at 812 to one or more subject actuators to inform the subject that (s)he is “dead”, for example a USB connected radio earpiece or an electrically actuated on-body buzzer.

FIG. 8b shows a parallel flow that may take place in a domain device, in this case associated with another “user” of the system, from another viewpoint another subject. From the viewpoint of one subject, other users are comprised in the domain. The flow of FIG. 8b begins with a server instruction being transmitted from a server to a device that an event should take place, as indicated by operation 820. In the illustrated example, other users of a system in a military training scenario are to be informed of mission failure. This can be achieved in several ways via user devices and/or one or more domain devices.

FIG. 8a shows a flow in which a subject device is configured to communicate directly with at least one of the plurality of subject actuators to transmit instructions based on the subject sensor data. From the viewpoint of one subject, the other users are comprised in the domain. Therefore FIG. 8b shows a flow in which a plurality of domain actuators (on the other users) cause one or more events in the domain in response to instructions from the domain device.

In response to receiving an instruction, a domain device may determine whether the instructed event, such as actuation of an actuator, has already taken place, at operation 822. This might occur for example if the instruction was retransmitted to the domain device following a lack of connectivity between the device and the server. Further it is determined at operation 824 whether the timing of the instructed event is suitable having regard to the progress of events or received sensor data. If the event has not taken place and is still suitably timed, it is implemented by the device transmitting instructions to actuators to cause one or more events, in this example to indicate to members of a team that their mission has failed, at operation 826. The actuators are shown in FIG. 8b to comprise an on body buzzer actuated by an electrical actuation signal and a USB connected radio earpiece that might play a message such as “drop dead”.

FIG. 8c shows a parallel flow that may take place in a domain device that might be associated with static equipment, for example installed in a building or fixed area. In this example the domain actuators are shown to be a strobe light, smoke machine and aroma machine. Other domain actuators described elsewhere here or such as might occur to those skilled in this art may be used.

At operation 840 a server may transmit an instruction to a device to cause one or more events indicating to a subject or user of a mission failure in an operation similar to operation 820. The flow may include steps 842 and 844 similar to operations 822 and 824 where it is checked whether the instruction has already been acted on and whether it is timely. In any of the systems described here a decision as to what kind of event to cause may be determined at the server or the device since both may include a policy store and decision engine. Therefore the server may transmit a general instruction which may be implemented in more than one way at the device and the decision as to what event should take place may be made at the device.

Examples of the device making a decision are shown in FIGS. 8b and 8c where the instruction from the server is a general instruction and the device may decide which actuators should be operated. Alternatively a specific instruction as to which actuators should be operated, optionally only if the timing is appropriate as already mentioned, and the device implements the specific instruction from the server.

In the example of FIG. 8c the device may make a decision to inform a mission failure by simulating an IED being activated. The objective of the mission may have been to prevent this. Thus at operation 846 IED effects are set off comprising one or more of strobe lighting, smoke and aroma, optionally via different communication technologies HTTP and serial protocol as indicated in FIG. 8c.

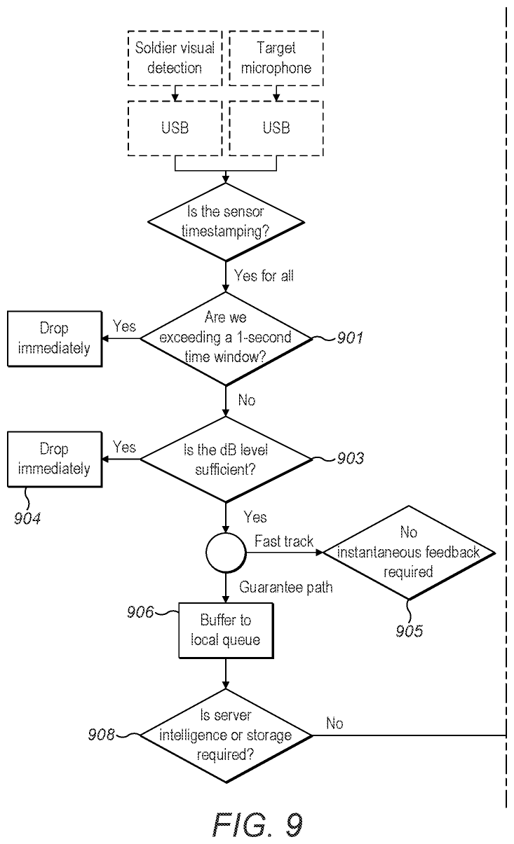

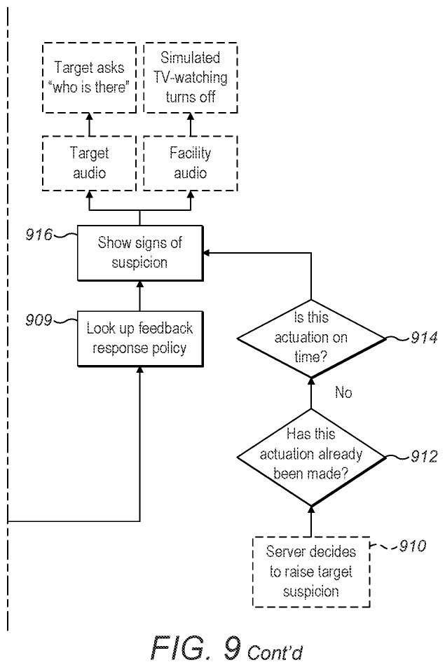

FIG. 9 is a flowchart similar to those shown in FIGS. 8a, 8b in which a domain device is configured to communicate with a server to receive instructions based on the domain sensor data to cause an event by the domain actuators. In this example the domain device is a smart target as defined in the foregoing but as the explanation will show the sensors and actuators could be otherwise installed in the domain. The flow is are similar to those described with reference to FIGS. 4-7 with the following additional or alternative details:

In the flow of FIG. 9 it is assumed that the target is provided with a microphone and a sensor for visual detection of a subject such as a trainee soldier. The sensor may be for example a camera with suitable image processing for person detection. The microphone and sensor are shown to use USB and Real Time Streaming Protocol “RTSP” connections respectively.

At operations 901 and 903, analogous to 501 and 503, a check is made as to whether a sampling frequency is exceeded, in this example 1 sample per second, and whether a detected sound is sufficiently loud, failing either of which the data is dropped at 904. In this example a fast track response is not required as indicated by decision 905. The data flow then follows a guarantee path. Sensor data is buffered at operation 906 and then a check is made at operation 908 whether server intelligence or storage is required, similar to operations 510 and 512 of FIG. 5. The guarantee path then continues in a similar way to that of FIG. 7 so is not repeated here.

In the flow of FIG. 9 server intelligence or storage is not required. The intention in the flow of FIG. 9 is to ascertain whether the subject's activity has aroused the suspicion of the “target”. The sensor data is then processed via a guarantee path similar to that shown in FIG. 7. This does not preclude the possibility that an instruction may be received from the server for an event to take place.

At operation 909 a feedback response policy at the domain device is consulted and if appropriate, at operation 916, an instruction is issued to one or more actuators to “show signs of suspicion”. Then an instruction is issued at the domain device to cause the event, in this case by simulating the sound of a TV being turned off and playing an audio recording “who's there”.

A decision may also be made by the server to cause an event, in this example “raising the target suspicion” at 910. A check is made at 912 whether this has occurred already, for example under instruction from the domain device, and whether to act on the instruction would be out of time in operations similar to operations 822, 824, 842, 844.

If the event is still “in time” and has not taken place already, an instruction is issued at the domain device to cause the event, again by simulating the sound of a TV being turned off and playing an audio recording “who's there”. So in this example flow the subject may be trained to be stealthy.

Any of the systems described here may include one or more autonomous actuators that do not require instructions from a server. For example, a target as described elsewhere here could be fully autonomous, for example with “built in” suspicion; it could be semi-autonomous where a suspicion policy is provisioned by the server (or a domain device) but decided by the target, in other words the target may be configured based on instructions from the server; or it could be entirely server driven, with the target behaving like a “dumb” set of sensors actuators.

An autonomous target may be provisioned with a number of policies determining how it should behave in different scenarios, for example determined by a combination of sensor signals, for example if suspicion is aroused. That might depend on the “personality” of the target. For example, instead of receiving an instruction from a domain device (optionally via the server), a target may “decide” to on an action, for example to switch off the TV and voice its suspicion. In another case, it might decide to yell for help; in yet another, it might decide to remain quiet. The “cases” may be part of rules that are operated by the target. Alternatively where the target is not autonomous those rules may be implemented by a device or server.

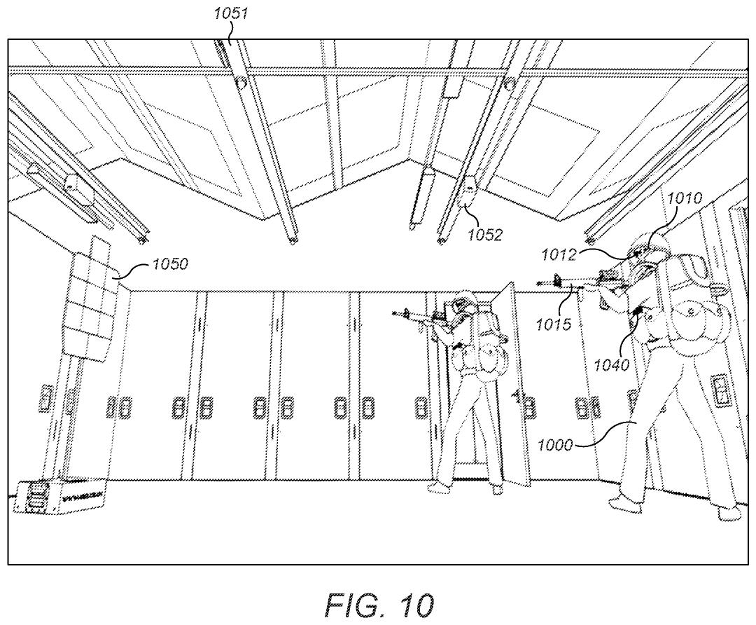

FIG. 10 is a perspective view of a subject in a domain using a system according to some embodiments of the invention, alongside another subject who may also be using such a system. In this example the domain is illustrated as a room, for example within a building, and the subject is equipped for a military training exercise. The subject 1000 is shown to be provided with a system as described elsewhere here comprising a plurality of subject sensors for monitoring the subject's behaviour including one or more body worn sensors and one or more remote sensors. The body worn sensors may in this example to include one or more biometric sensors, for example in the subject's helmet 1010, eye tracking sensors 1012, for example in a headset, and a weapon tracking sensor on a weapon 1015 held by the subject. These sensors communicate in one or more ways with a subject device 140. The system optionally also includes one or more remote sensors for monitoring the subject's behaviour, shown in this example to be included in a target 1050 and arranged to transmit information to a subject device 1040. Subject device 1040 is worn by the subject and arranged to receive sensor data from the body worn sensors and optionally from the remote sensors. The device 140 is shown in this example to be worn on the subject's waist. The subject device 140 may be a personal situation monitoring device that also functions to inform the subject about a current situation, for example via user interface such as a visual display, to assist the subject in decision making. A server, not shown, may be arranged to receive sensor data from the subject device 1040 and to transmit instructions based on the subject sensor data.

A domain device, not shown, may be located in the domain to receive instructions from the server 120. This may be for example hidden behind a wall panel or in some other suitable location. Domain actuators may be provided for causing one or more events in the domain in response to instructions from the domain device. In the example of FIG. 10, the domain actuators are shown to include actuators in the smart target 1050, lighting 1051, and one or more speakers 1052. Others may be provided as described here or as known to those skilled in the art.

It will be appreciated from the foregoing that as well as providing a training, gaming or other simulated environment, systems as described here are able to accumulate comprehensive data relating to the behaviour of a subject which may be played back after an exercise to evaluate the subject's behaviour and learn from it. The combination of the various sensor data, optionally in addition to video surveillance that may be provided, is a rich set of data for training or other purposes.

As noted in the foregoing the systems described here are not limited in terms of the number of subjects and the number of domains. For example the system described with reference to FIG. 1 may be extended to include multiple subject devices to be worn by respective subjects and optionally multiple domain devices to be located in different domains. These may communicate with the same server. With multiple domains and subjects, an event in a domain may be caused based on sensor data from a subject device worn by a subject in a different domain. The domains may be geographically separate. This possibility may be used to allow subjects to interact with each other in different locations which may be widely separated, for example by many miles. In a simple example, geographically separated domains may be configured, through the use of suitable sensors, to behave as relatively proximate areas, for example adjacent rooms. Thus a subject in one domain may respond to activity in another domain such as but not limited to sounds, simulated effects such as explosions and “drone strikes” and others to be discussed further in the following. Further, a subject in one domain may respond to activity by another subject in another domain. From the point of view of one subject, other subjects are part of the domain in which they operate.

The systems described here may allow for interactivity between subjects in different domains without the need for synthetic effects. Events such as explosions and others can be simulated using actuators as described here. Other real events such as but not limited to lights turning off, temperature changes, replay of speech, similarly do not require synthesis. Events may be simulated for an individual in a real environment using physical effects. Thus a system may be provided to facilitate interactivity between individuals in geographically separated locations avoiding the expense and complexity of synthesising the activity of one individual for the benefit of the other.

Systems using multiple domains may use any of the arrangements of sensors, actuators and devices for subjects and domains described in the foregoing, but need not be limited in this way and are not restricted to the transmission of all sensor information to subject or domain devices. Some sensor data may be transmitted directly to a server for example and some actuators may be controlled by a server rather than via a domain or subject device.

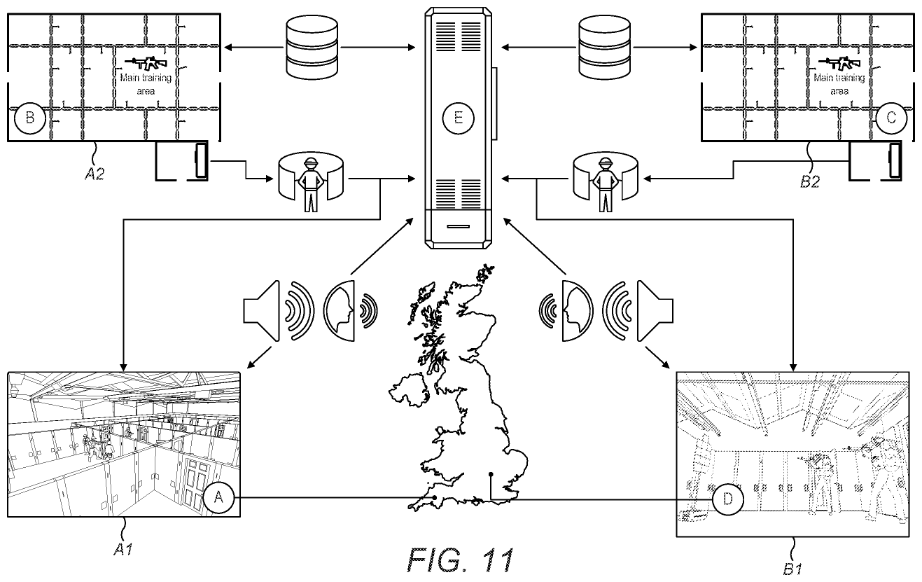

An example of a system comprising geographically separate domains is shown schematically in FIG. 11. In this example two domains each comprise a facility, shown as separate buildings in plan view A2, B2 and perspective view A1, B1 at different locations in the south of England. Here it can be seen that by creating a data linked environment, multiple facilities may communicate with each other to create a synthetically larger co-located space which in reality is geographically dislocated. So for example if a subject was shot in domain A, speakers in domain B could play the sound of gunshot so that subjects in B would feel that the other facility was e.g. “just over the wall”. These effects may be created using suitable flows of digital information including sensor data and actuator instructions, possibly including audio effects, voice communications and other effects. Facilities such as these may be used to collect training performance data. Communication paths, a computer system and data storage are shown schematically in FIG. 11. It should be noted that in any of the systems described here, in addition to or alternatively to the relative proximity of different domains being simulated, their relative orientation may also be simulated so that the direction from one to the other is simulated to be different from the actual direction. Also the relative height of one domain, e.g. building, relative to another may be simulated, so that two domains on a similar level may be simulated so that they are in different storeys of the same building. With different buildings providing different domains, one may represent the ground floor and another may represent the top floor which may be immediately above the ground floor or higher. Any number of separate domains may be provided although only two are shown in FIG. 11 for simplicity.

Each domain may be provided with additional effects to make it more realistic, for example with background sounds appropriate to the environment being simulated. It should be noted that although each domain as illustrated is shown to be confined by walls, it may be used to simulate an outdoor space. For example, one or more interior walls one building at one physical location may simulate one or more exterior walls of another building at another physical location, to simulate one subject or group of subjects being outside a building occupied by another subject or group of subjects.

It should be noted that a relationship between buildings may be simulated, such as one comprising control functions for another. For example one building might represent an electrical station that controls the power for another building and the cutting off of power to a building might be simulated.

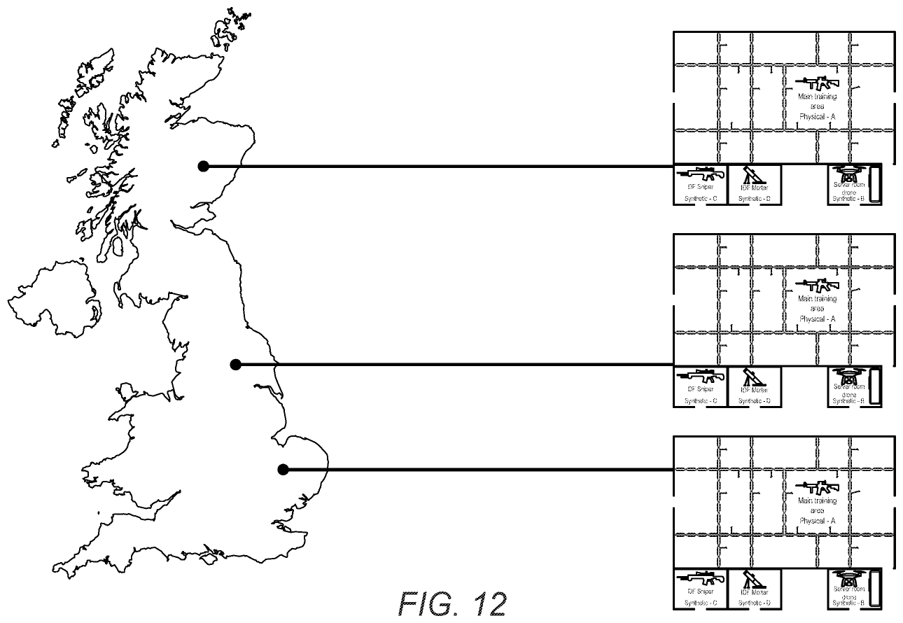

FIG. 12 shows an alternative example of a system comprising geographically separate domains, in this example three domains, each of which may represent a different building in a compound or village, for example as shown in an aerial view in FIG. 15. Here using communication of data and instructions between domains, the domains may be simulated to be in close proximity, e.g. within hearing distance of each other, although they may be separated by many miles.

In all of the systems described so far, all of the simulation of events may be achieved using real, or physical, effects. No synthetic effects are required.

It will be appreciated from the foregoing that a domain as described here may provide a particular environment, e.g. for training, gaming or any other purpose. Such a domain or environment may be open, e.g. without walls or other physical boundaries, or closed in which case it is not necessarily limited to a single room. The real environment may comprise a building with multiple rooms or even multiple stories.

As shown in FIG. 10, more than one subject may be present in the same domain. In a system comprising multiple domains, the system may be configured so that the domains represent non-overlapping spaces in the synthetic larger space. Then, all interactivity between subjects is ensured to be at a minimum range and this facilitates the simulation of events resulting from sensed data. For example, it is not necessary to simulate the possibility of subjects touching each other.

It is desirable for the simulation of events to use physical objects and effects where possible. The end result may be a more realistic user experience, and may be more cost effective depending on what is being simulated.

In general a simulation may be real, e.g. use physical objects and effects, or virtual. A purely synthetic simulation, such as may be provided via virtual reality headset, may offer exceptional visual potential but lacks the fidelity that might be desirable in some training and other implementations. A particular example where it is desirable to maximise use of a real environment is in close combat training. The technology described with reference to FIGS. 1-12 may be used to simulate real life events without the need for virtual effects. Thus a subject or a team of subjects in a domain may have an experience as close as possible to physical reality. Nevertheless systems as described here allow for the possibility of events to be synthesised to extend the range of experiences that may be provided to subjects. In particular some systems described here allow for real and virtual activities to take place contemporaneously and to influence each other in real time.

Such systems may comprise apparatus for providing a virtual environment to a real individual, one or more sensors for sensing activity by a real individual in a real environment, and simulation apparatus for simulating events for an individual in a real environment using physical effects.

Thus according to some aspects of the invention, the behaviour of one or more individuals in a virtual environment may be used to simulate an event in a real environment using physical effects. For example a mortar fire initiated by one individual using virtual reality may result in an event in a real environment simulating the mortar fire. The physical effects may include any of sound, light, vibrations, aromas and any others for example known to those skilled in special effects. Conversely the behaviour of one or more individuals in the real environment may be used to simulate an event in a virtual environment.

A facility or domain such as A or B shown in FIG. 11 may be provided with effects simulating a variety of environments. To take the example of a building in a desert this may be achieved using effects such as wall coverings which may be in the form of material applied to the walls or images projected onto the walls, sound effects and others which will be familiar to those skilled in this art.

The environment beyond the domain accessible to the subject may also be simulated to provide a more realistic experience for a subject, for training, gaming or other purposes. Subjects may then forget that they are confined in their movements by walls or other boundaries. For example, sounds apparently outside the domain may be provided. Further a subject may be provided with a view of or from the area or space apparently outside the domain in which the subject is able to move, for example in the form of an apparently real time video feed. This “extended view” may be simply achieved for example by projecting images onto windows in a building. For a more realistic experience, particularly but not exclusively suited to a military exercise, a subject may be provided with a view of the area in which the domain is apparently situated, for example an aerial view, which may be in the form of a video feed from a drone or other aircraft, or a view from a different perspective such as might be provided by a CCTV camera, for example for an urban exercise. In other words an individual might have a view from a perspective not available to the individual using his own eyes.

Thus there is also provided here a system for simulating a real environment using physical effects within a domain, augmented by a view of or from an area or space apparently outside the domain. In this system or in any of the other systems described here, all events within a defined domain may be real simulations of real events, and spaces beyond the defined domain may be synthesised.

This view may be rendered on a device carried by the subject, the same as or additional to the subject device described elsewhere here, for example a tablet computing device or smart phone such as an IPad or Samsung Galaxy S9 or other suitable device. As known in the art, such devices may be provided with a geospatial infrastructure and military situation awareness application, such as the well-known Android Tactical Assault Kit “ATAK”. “Subjects” are also referred to here as “real individuals” to distinguish them from simulations of individuals using either physical apparatus or computer simulation. The “extended view” mentioned above may at least partially comprise a virtual environment in which another individual may operate.

It will be appreciated that an aerial or other view as described above need not include any area outside the domain in which a subject is able to move and, depending on the exercise for which a system is configured, may be restricted to that domain, in which case it may be synthesised based on sensor information or may use real camera footage. Further, such a view may include any combination of the subject's real domain and a virtual domain outside the real domain using any combination of real and synthesised imagery. Importantly a subject may be able to see him/herself in such imagery as (s)he moves around the domain.

The video feed may be synthesised or may comprise real images of an area, typically foreign to the actual geographical location of the domain. For example a desert or other alien environment may be simulated in England. The image on the right in FIG. 12 is an example of a video image that might be presented to a subject. The subject may have the ability to “control” the aircraft, for example to view the area from different angles or heights. The video imagery may be in any suitable form such but not limited to colour for simulation of a daytime activity or thermal, e.g. infrared, for simulation of a night-time activity, any of which may use real or computer generated images.

The provision of a view of an area outside a subject's domain may be used not only in systems where multiple domains are provided, but also in single-subject systems. Thus there is also provided here a system for monitoring the behaviour of a human or animal subject and initiating one or more events in a domain in response to the behaviour, comprising a plurality of subject sensors for monitoring the subject's behaviour which are not limited in terms of their location and may also serve as domain devices. A subject device may receive sensor data from the sensors. The system may further comprise a server arranged to receive sensor data from the subject device and to transmit instructions based on the subject sensor data, a domain device to receive instructions from the server; and a plurality of domain actuators for causing one or more events in the domain in response to instructions from the domain device. The system may be further configured to provide a subject with a simulated view of an area in which the domain is apparently situated. Thus a real e.g. closed environment may be augmented with a synthesised view of an area or space apparently beyond the real environment. The real and simulated environments may be configured so as not to overlap. The simulated view may be provided via the subject device. Thus the subject device may function as system controller as well as simulation equipment. The functions of the server and the domain device may be incorporated into the subject device so that it is not necessary to provide a separate domain device and server. Alternatively the system may be configured in the same manner as any of the other systems described here.

In some embodiments the real environment may be defined as one in which no dedicated viewing or other sensing equipment is required in order for a subject to experience it. Thus although it may be augmented with synthetic imagery, presented for example on a display device, provided that the real and simulated environments or spaces do not overlap, the real environment is no less real. The display device may present a portal to a synthetic world beyond the real environment.

Although it is desirable for subjects to experience reality as far as possible, the experience may be improved with further virtual effects, for example but not limited to enabling subjects in a real environment to interact with subjects in a virtual environment, and optionally vice versa. As noted elsewhere in this document, some systems described here allow real and virtual events to take place contemporaneously and to influence each other. For example, a system may be designed to be used by one or more subjects in a real environment, and one or more subjects in a virtual environment.

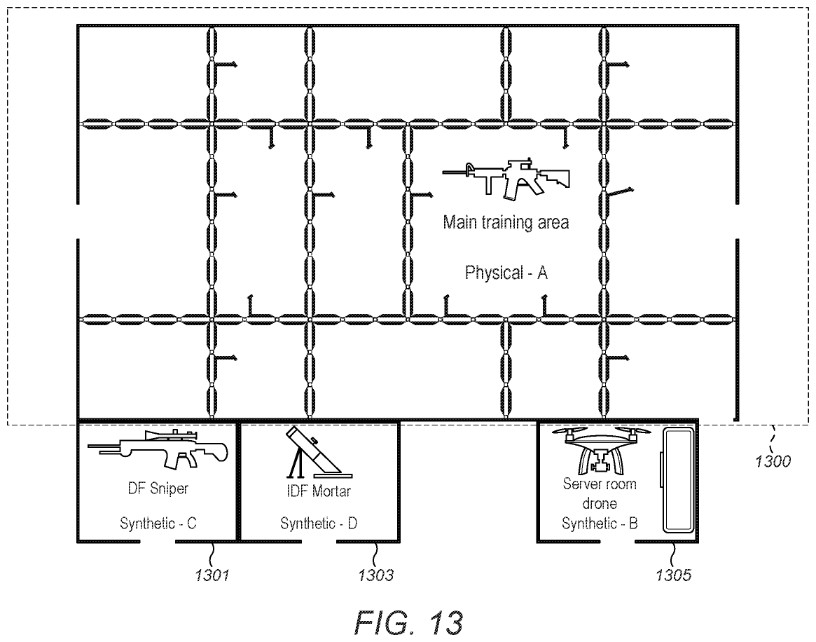

FIG. 13 is a floor plan of a facility which may accommodate subjects respectively in real and virtual environments in the same building. It will be appreciated that subjects in real and virtual environments may be geographically separated and the subjects, or the respective environments, may be provided with communications devices to enable them to interact with each other. In general such communication may be configured in a similar manner to interactive gaming where participants communicate via the internet. However in contrast to some interactive gaming configurations, one or more subjects may act in a real environment whereas one or more others may act in a virtual environment, i.e. synthesised, for example using a virtual reality headset or other visual aid.

In FIG. 13 the rectangular area 1300 bounded by a dotted line represents an area, or domain, in which a real environment may be provided. A subject in this domain does not need a virtual reality headset for example to experience the environment.

The rectangular area 1300 may be divided into rooms for example as shown in FIG. 13.

Additional domains, e.g. rooms 1301, 1303, are provided in the facility shown in FIG. 13 in which additional subjects may interact with subjects in the domain 1300. In either of these domains, subjects may experience a virtual environment, for example using a virtual reality headset. For example, sensor information from a real domain or environment, may be used to create a virtual environment for a subject. The sensor information may include information sensed from activity by a subject in the real environment.

Provided that the real and virtual environments are configured to represent non-overlapping spaces, it may not be necessary to simulate a subject in the virtual environment. All interaction may be at a range, for example such that the individuals would not be expected to be visible to each other either at all or in detail.

In the field of entertainment it has been proposed to present and permit concurrent interaction by players of a game such as baseball within multiple reality and virtual reality environments as if both were located within the same environment. This requires amongst other things ultra-precise positioning systems and currently available sensing is not sufficient to create a realistic team game experience in this way. By contrast, any of the systems described here may be configured such that the real and virtual environments represent physical spaces that do not overlap.

In some systems the subjects may be invisible to each other, or one is invisible to the other but not vice versa. This more closely replicates many real life situations, for example where a hidden enemy is present, but may also simplify the system since it is not necessary e.g. to try to simulate one subject for the benefit of the other. In other words, some systems as described here take advantage of the fact that not all individuals in real life situations are visible to each other. This advantage is used to create a simpler and more cost effective system which is at the same time more realistic for at least some subjects by not requiring special viewing, or optionally other sensory, equipment. For example a subject in a real environment does not require special viewing equipment to view an avatar of another subject. The real environment may be visible to a subject with naked eyes. More generally, in any of the systems described here, the real environment may be configured not to require any dedicated sensory equipment for use by a subject in the real environment. In other systems as described elsewhere here a subject in the real environment may be provided with limited haptic feedback.

The particular example shown in FIG. 13 is for a military exercise where room 1303 may accommodate a subject acting as sniper or other enemy of subjects in the domain 1300. It would be typical for a sniper or similar enemy not to be visible to its enemy. The sniper or other subject or subjects in room 1303, which represents a domain for those subjects, may be presented with video imagery of activity taking place in the domain 1300. This may be used to synthesise a virtual environment for the enemy subject(s) who are thus one or more real individuals (as opposed to e.g. avatars) in a virtual environment. The imagery may be a projected virtual simulation and may be generated in a similar way to a drone camera feed and updated in real time, for example with motion or other inputs derived from subject or subject domain sensors as described elsewhere here. Individuals in the virtual environment may be provided with weaponry as is known in the field of virtual reality, to shoot one or more virtual targets such as virtual representations of real subjects in the domain 1300. The system may be configured such that this kind of action causes simulation of an event in real time for one or more of the subjects in the real environment, e.g. simulation of a subject being shot, for example by providing safe haptic feedback. This might be accompanied by an audio message to the individual such as “you're dead” to confirm the severity of the injury inflicted by the shot. Both of these are real rather than virtual events.

Similarly, for a military exercise, room 1301 may accommodate a subject acting as an operator of a mortar or other weapon operable for or against one or more subjects in the domain 1300. For example a subject in domain 1300 might call for a mortar to be fired, for example via short range communication with a mortar operator. As with the example of the sniper, the subject acting as mortar operator may be provided with a virtual environment, for example via a VR headset, representing what a real mortar operator would know of activity taking place in the domain 1300. The mortar operator may be another example of a real individual able to take an action in a virtual environment which may cause simulation in real time for a real individual in the real environment. The mortar operator may operate independently whether or not (s)he is an enemy of subject(s) in the domain 1300.

In some systems a mortar operator may be provided that simply responds to a request from a subject in domain 1300 in which case a human operator may not be required.

The simulation of mortar fire may be achieved using real effects in a safe way such as smoke, sounds, vibrations, a flash of light and other effects which might be expected as a result of a mortar exploding in the domain 1300 or its vicinity. All of these may vary according to the direction and distance from which the mortar was fired so as to mimic a real life situation as closely as possible.

Also shown in FIG. 13 is a server room 1305 housing computing equipment such as one or more servers as described elsewhere here. Different views of an environment, such as drone feed or CCTV camera footage, may in some systems be generated here.

It should be noted that where different environments are geographically separated but intended to appear to be physically closer together, the communications and computing infrastructure may be implemented in any suitable manner that would be familiar to those skilled in this art. A central server at a separate, e.g. cloud, location might serve all environments, both virtual and physical. Alternatively different environments or domains might operate in a master/slave arrangement where a computing system at one serves the others. The processing and other computing operations required to implement the methods and systems described here may be implemented in one computing system at one location or shared between different systems, for example according to available computing power.

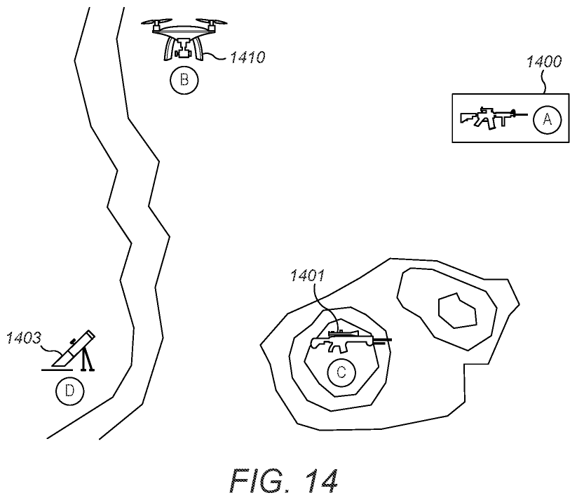

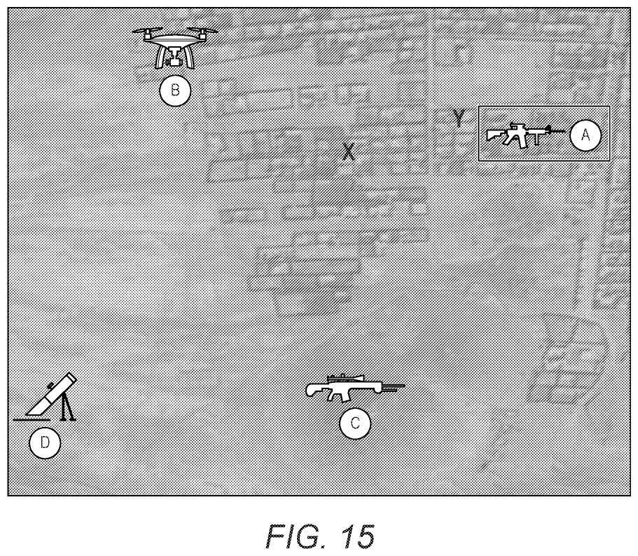

FIG. 14 is a schematic diagram showing one example of how the real and virtual environments of the kind shown in FIG. 13 may be configured to represent a real life situation, for example a military situation. Using simulation, either synthetic or real or a mixture of both, the different environments of FIG. 13, e.g. different domains A, B, C, D shown in FIG. 13 as different rooms, may appear to subjects to be oriented differently to each other from the physical reality and spaced from each other differently. To take the example of spacing, geographically separated environments may appear closer, for example within sight of each other, and close environments such as adjacent rooms may appear further apart.

A common feature of all the systems described here is at least one real environment in which subjects use weapons, their eyes, ears and bodies as normal for the most realistic experience. The real environment may be provided in a dedicated facility, e.g. building or part of a building. This may be rendered using synthetic techniques into a structure of the same size. In FIG. 14, the rectangle 1400 also labelled A corresponds to the domain 1300 of FIG. 13, which may be occupied by one or more subjects carrying weapons. A sniper 1401 also labelled C is represented by a weapon on a mountain top at some distance from the domain 1300, within telescopic sight range of domain 1300. A mortar 1403 also labelled D is shown on a mountain ridge overlooking the domain 1300 and surrounding virtual area. A virtual drone is indicated at 1410. This may be “controlled” by a subject in the real environment. In other words a system may be configured for a real individual to control the visual display in the manner of controlling an aerial vehicle to determine the area displayed. In the particular scenario described here this may enable the subject to spot the sniper or mortar operator. The virtual drone may be weaponised, whereby the subject may use a drone weapon for an attack purpose. More generally, one or more predetermined actions by a real individual in a virtual environment, e.g. those that would be expected to be visible from the air, may be simulated to an individual in the real environment via a visual display and optionally also for one or more real individuals in virtual environments.

It will be appreciated that in any of the systems described here the virtual environment may represent a space immediately adjacent to the real environment, or at least sufficiently close that individuals in the real and virtual environments may interact with each other. In other words, a virtual environment may “extend” the physical environment of a training, gaming, or other facility. In the context of military training this is useful for approach work where enemies may be located outside the physical space in which an individual can move. However the interactions may all take place at a range, which may be simulated, and as noted elsewhere the virtual and real environments may be configured not to overlap. This not only improves the reality of any simulation in the real environment but also enables the provision of a simpler and more cost effective system.

The combination of real and virtual environments may replicate a real environment, e.g. war zone. This is illustrated in FIG. 15 where the same locations of items in FIG. 14 are overlaid on an aerial view of a mountain village. A number of scenarios may be played out for training, gaming or other purposes. In one example, a “commander” in a physical environment, for example domain 1300, might ask for support from a mortar operator on a target west of the physical environment at position X. The mortar controller could be able to see the target location in a virtual environment, for example using a virtual reality headset. After operation of the mortar by the mortar controller, a real individual in the virtual environment, this may be simulated for the commander, a real individual in a real environment, for example as a result of being “seen” by the virtual drone and optionally also for one or more other real individuals in virtual environments such as the sniper at location C. A sound of an explosion could also be played to individuals. In the case of those in virtual environments this would be e.g. via a VR headset. In the case of those in the real environment this could be via a speaker in the domain 1300. For those in the real environment this avoids the need to synthesise the relative distance and orientation of each individual with respect to the source of the sound.

If the virtual mortar fire did not hit its target and for example was aimed at location Y closer to location A, an event might be simulated affecting one or more individuals in the real environment depending on their exact location, such as the killing or injuring of one or more individuals. The simulation might be as simple as an audible or text message or may involve the use of haptic effects. Suitable speaker arrangements may be used to simulate the effects of events, such as explosions, at different locations.

It will be appreciated that a strike by a drone may be simulated in a similar way to a mortar fire, using physical effects as appropriate in the real environment and synthesised effects in the virtual environment. In addition to the effects already mentioned, heating or climate control may be used in the simulation of an event such as an explosion, to simulate the heat that might be generated from a real explosion, for example as a result of fire caused by the explosion.

As noted earlier, several domains described with reference to FIGS. 1-13 may be provided in a system and they may be adjacent to each other or geographically separated. This possibility may be used to allow subjects to interact with each other in different locations which may be widely separated, for example by many miles. Any of the domains described may be used to create any of the real environments described here. Dedicated facilities, e.g. for training, gaming or other purposes lend themselves particularly well to this kind of application.

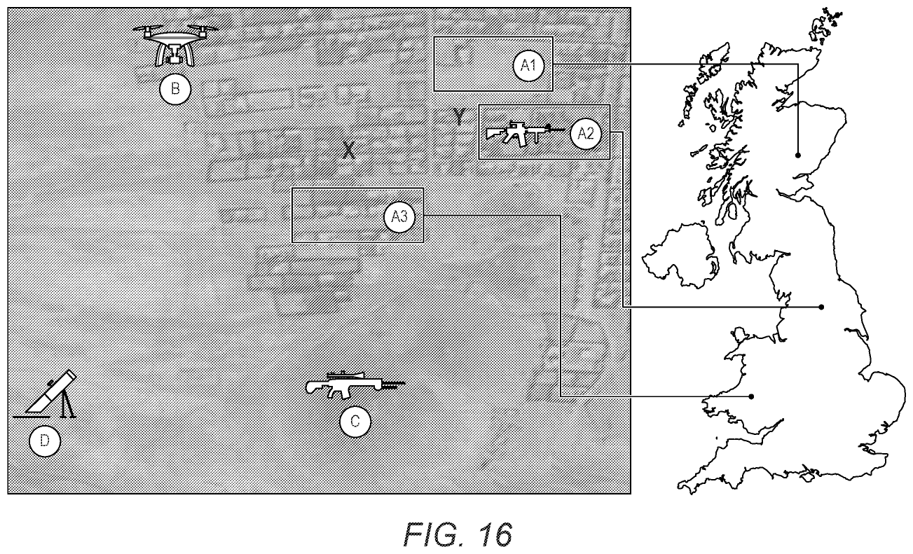

Therefore an important aspect of some systems described here is that by, different facilities, which may be geographically dislocated, may be inserted into a virtual space so as to be synthetically co-located. For example, different training areas which may be provided in different dedicated facilities may be synthetically merged to create a village. This may simulate a real village if desired. The relative spacing and/or orientation of the facilities may be different from their actual or physical spacing and orientation. An example of this is shown in FIG. 16 where facilities A1, A2, A3 providing real environments are inserted into different virtual spaces of the same village shown in FIG. 15. The facilities are physically located in different parts of the UK at different distances and orientations from their virtual locations in the village. Similar virtual environments B, C, D to those shown in FIGS. 14 and 15 may also be provided. If an individual was shot in facility A3, speakers on the western aspects of A1 and A2 would play gunshot sounds. While the environment outside each of the facilities may be synthesised, an important aspect of some systems described here is that the environment inside each facility is real and all events inside the facility are real, albeit that they may simulate real events.

Notably in any of the systems described here the real and the virtual environments represent geographically separate locations, such as the building or buildings and locations overlooking the building(s). In other words, systems may be configured such that there is no overlap between the real and virtual environments, although they may be adjacent to each other. Therefore it is not necessary to accurately replicate the real domain in the virtual domain or vice versa. This is in contrast to interactive games which attempt to allow individuals in real and virtual environments to play games in the same space and to interact with each other, which are not only expensive in terms of required computing power but also technically challenging in terms of accurately replicating the respective domains.

Further, an individual in the real environment may in some systems be able to view the virtual environment, for example via a subject device seeing for example the drone feed, and to cross from a real environment representing a first area into a real environment representing a second area which the subject has viewed in the virtual environment. Real immovable objects in the real environment such as targets described further below may be represented as movable objects in the virtual environment.

Some systems described here allow for events that are not necessarily caused by individuals or subjects acting within the systems. For example an exercise may be set up for individuals including a number of predetermined challenges which one or more individuals are intended to address. An example is the placement of a “bomb”, for example a dummy bomb, in a real environment, for example behind a door. Some clues as to the possible presence of the bomb or other challenge may be provided, such as noises suggesting activity by an enemy, played over one or more speakers. An individual in a virtual environment might be presented with a synthetic rendering of the challenge being set up, such as the placement of the bomb, for example if it was placed in a building with no roof which is common in some desert environments. A subject in the real environment might avoid detonating the bomb, in which case they are able to defuse it. Otherwise the bomb detonation is simulated using real effects such as any one or more of light, sound, smoke, aroma and other suitable effects. The detonation of the bomb may also be simulated in the virtual environment, for example to the mortar operator or sniper mentioned elsewhere.

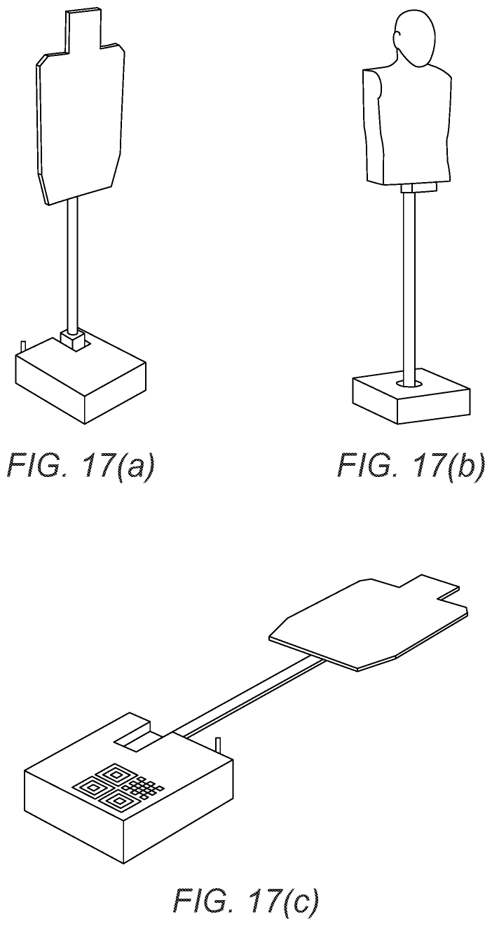

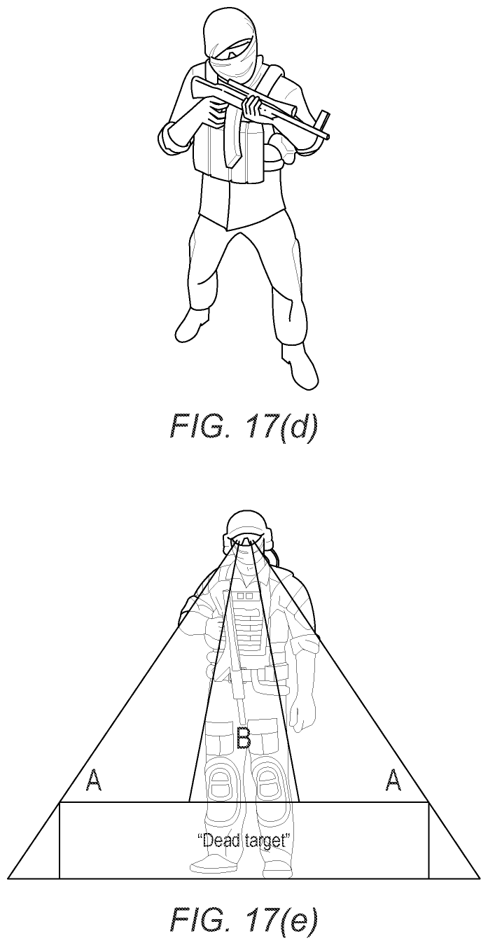

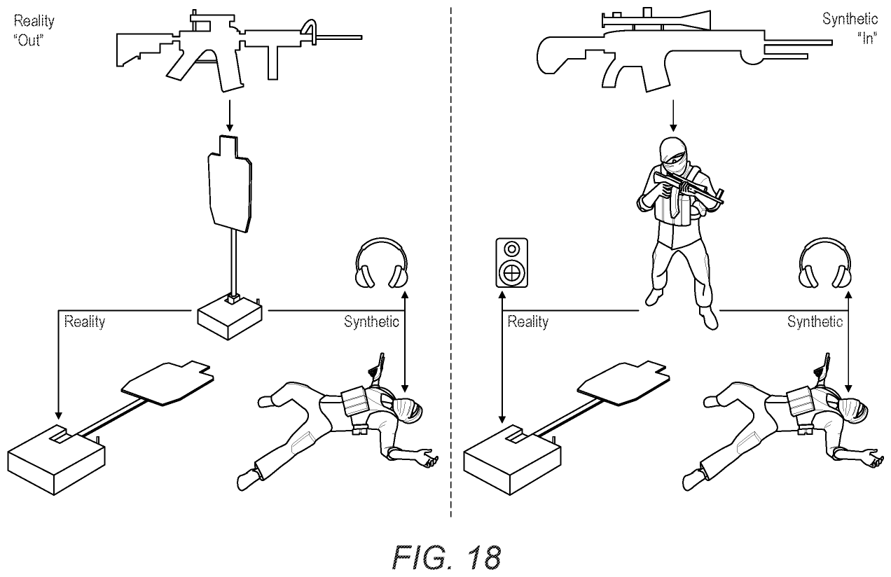

Some systems described here allow an individual to be simulated in the real environment, for example as a potential target for another individual in the real environment. This will now be explained with reference to FIGS. 17 and 18.

FIGS. 17(a) and (b) show two examples of physical targets that may be provided in a real environment, one two dimensional and one three dimensional, representing individuals. These may be digital or “smart” targets as described elsewhere here. They may include geolocation technology so that they do not need to be accurately placed on set up of an exercise and the system, e.g. server, can receive data relating to the target location for the purpose of synthesising in a virtual environment. FIG. 17(c) shows a “dead” physical target. The physical target may be represented in a more life-like manner in a virtual environment, for example as shown in FIG. 17 (d). This might be animated to make it more realistic than the purely static real target. Further, an image of a real or physical target may be converted into a more life-like image. This may be useful in military training for post incident reporting where for example the reporting of dead combatants is important. FIG. 17 (e) shows schematically how an image of a physical target might be converted into a realistic image, again for the purpose of creating a more realistic experience. A system may be configured, for example using a suitable app on a smart phone, to enable the scanning of a target to produce an image of a human. This could be achieved using techniques similar to the use of the well-known ArUco Markers in computer vision applications. Further, the use of facial recognition in real life situations to identify dead bodies could be simulated to “identify” a “dead” target.

The relationship between synthetic and virtual events is further illustrated schematically in FIG. 18. In the real environment, an individual may shoot a target using a real (non-lethal) weapon as shown on the left of the figure. Here, as indicated at the top left of the figure, there is an output in reality from the gun leading to a sensor input e.g. to a sensor on the target. If successful the real target will fall over in reality. For anyone viewing the scene in a virtual environment, such as a sniper with a virtual telescope, the killing of the individual may be visible in the synthetic environment where in this example the target appears more realistic. The real and virtual images are shown at the bottom left of FIG. 18. This is an example of an action by real individual in a real environment causing simulation of an event in real time for another real individual in a virtual environment. In the synthetic environment, an individual such as a sniper may shoot a virtual target using a synthetic weapon as shown on the right side of the figure. Synthetic weapons, such as the sniper's rifle, may replicate the effects of a real weapon (such as recoil) but there is no projectile in reality (only synthetic). Real weapons have real projectiles, albeit non-lethal for training purposes. In the scenarios shown on the left and right of FIG. 18, the target may be the same, in other words it can be shot from either the real or the virtual environment. Again the killing may result in the corresponding physical target falling over and the killing being visible in the synthetic environment. This is an example of an action by a real individual in a virtual environment causing the simulation of an event in real time (the falling over of the target) for another individual in the real environment. The events, in this example killing of one or multiple targets, may take place contemporaneously. Indeed both individuals in the real and virtual environments may attempt to shoot the same target at the same time. This general principle is applicable to other events than the shooting of targets other than those representing other individuals, where the same target is available to subjects in both the real and virtual environments. Example targets include but are not limited to lighting or lighting control circuitry to plunge a space into darkness, and any other electrically controlled items.

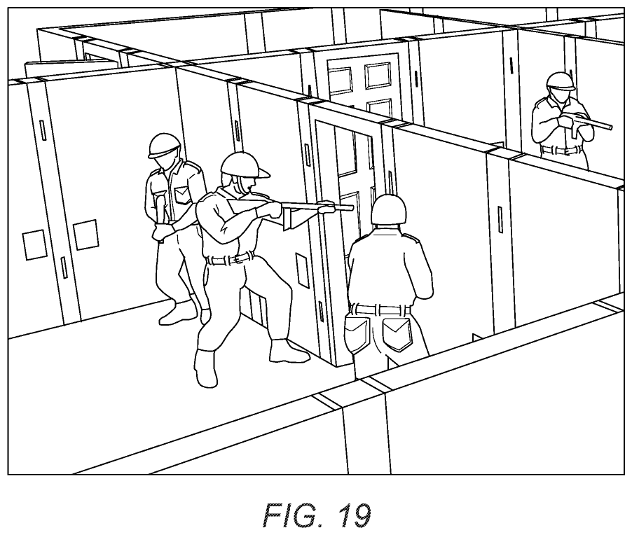

It will be appreciated that for an individual having a virtual overview of activity in the real environment, it would be necessary to render in the virtual environment individuals in the real environment. FIG. 19 shows schematically a synthesised view of the real environment such as might be visible to an individual in a virtual environment. This may be achieved in various ways. For example the motion of individuals in the real environment may be tracked, including motion of their heads and their weapons using sensor technology known in the art. The sensor outputs may then be used to create a virtual rendering of the individuals. The view shown in FIG. 19 might be a desert type environment where not all buildings have roofs. For buildings with roofs a partial render might be provided, for example showing views through windows.

Some systems may use techniques to achieve a smooth transition by an individual from a virtual to a real environment. If the real environment such as domain 1300 was simulating an environment open to the air, a drone would be able to view what was on the other side of a wall from a subject or individual, which could then be rendered to the subject via a subject's device, e.g. tablet or smart phone. This would be a synthesised view and could include a synthesised individual moving behind the wall. Once a real subject had crossed the wall, e.g. by opening a door, the individual could be shown in the synthetic environment to move quickly to the position of the stationary real target so that the target is at the position where the real subject expects it to be from having viewed the synthetic drone feed. More generally, a space in the real environment may include one or more items in a fixed location that is represented by a movable item in a corresponding space in the virtual environment. Each such item may be which is moved to the fixed location in the virtual environment as a subject viewing the virtual environment moves into the corresponding real environment. An animation of the movable item, e.g. individual, could be created in advance and then modified for the available space, for example to avoid the synthetic motion taking the item through real walls.

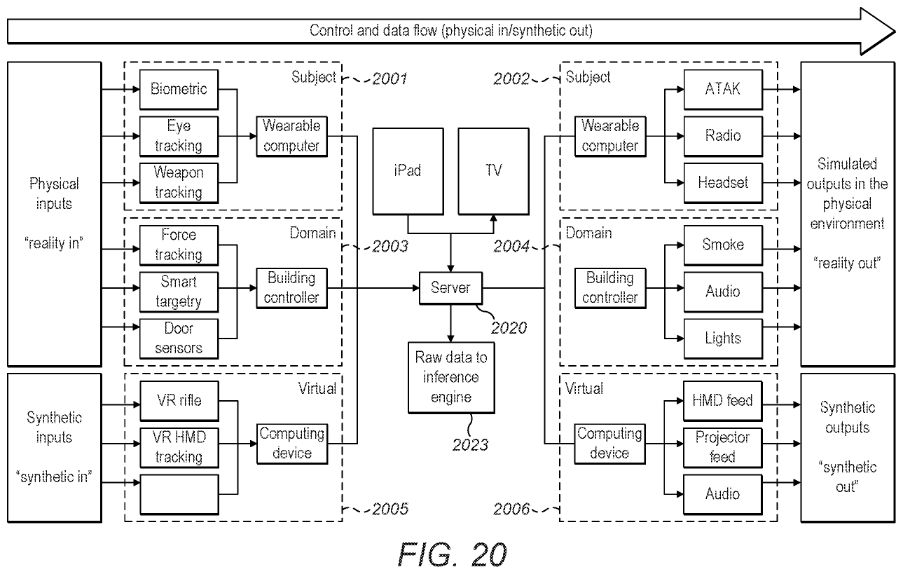

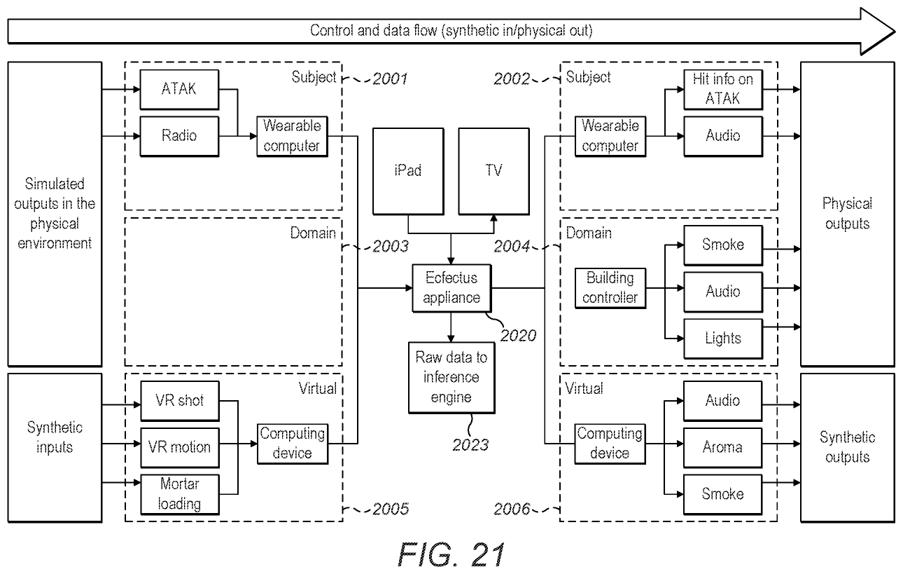

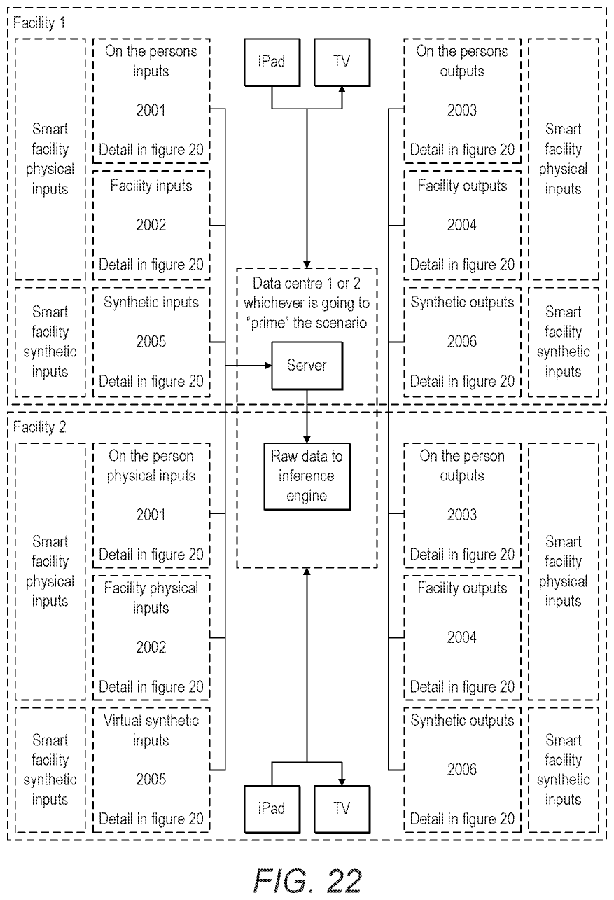

FIGS. 20-22 are schematic diagrams showing systems similar to those of FIGS. 1-3 adapted to allow real and virtual events to take place contemporaneously and to influence each other. These are shown by way of example only and such systems are not limited to the computing and communications architecture shown in these figures.

The system of FIG. 20 is similar to that of FIG. 2 and comprises examples of subject sensors communicating with a subject device, as indicated by box 2001, and examples of subject actuators communicating with the same subject device, as indicated by box 2002, examples of domain sensors communicating with a domain device as indicated by box 2003 and examples of domain actuators communicating with the same domain device, as indicated by box 2004. Any of these actuators, either associated with the domain or the subject or a combination of both, may provide simulation apparatus for simulating events for a real individual in a real environment using physical effects.

Additionally, the system of FIG. 20 is shown to comprise apparatus for providing a virtual environment to a real individual. This is shown to comprise sensors communicating with a virtual environment computing device, indicated by box 2005, and actuators communicating with the same virtual environment computing device, indicated by box 2006.

The virtual environment computing device communicates with a server 2020 in a manner similar to the subject and domain devices described with reference to FIGS. 1-3, so that computing devices associated with the virtual and real environments send and receive signals to and from the same central server.

It will be noted that in the example system of FIG. 20, in the virtual environment, the subject and domain sensors and actuators are not represented separately and separate subject and domain devices are not illustrated, since in a virtual environment, particularly if implemented via a headset, the subject and domain are not necessarily separated.

The system may be configured, for example through the use of a decision engine, or inference engine as shown in FIG. 20, such that an action by a real individual in the virtual environment causes the simulation of an event in real time for another real individual in a real environment, by the simulation apparatus. This may be via the synthetic inputs or “synthetic in” to box 2005 as shown in FIG. 20, communicated to the server 2020 resulting in simulated outputs in the physical environment or “reality out”.

Similarly the system may be configured such that an action by a real individual in the real environment causes the simulation of an event in real time in the virtual environment for the other real individual. This may be via the physical or “reality in” inputs as indicated in FIG. 20 leading to synthetic outputs as indicated in FIG. 20.

In the example of FIG. 20, physical inputs and optionally synthetic inputs from the virtual environment are shown to result in a range of simulated or physical outputs and synthetic outputs in the virtual environment 2006.

FIG. 21 shows a system similar to that of FIG. 20 where synthetic inputs lead to physical outputs, for example an action by an individual in the virtual environment may lead to simulation of an event in the real environment. Here sensors in the virtual environment may sense any of a shot, motion or mortar loading. The result in the real environment may be any one or more of hit information on a subject or individual's device, audio to the individual e.g. via an ear piece, any one or more of smoke, audio and lighting effects in the domain thereby sensed by all individuals in the domain. In addition the virtual action in the virtual environment may lead to similar virtual effects such as audio, aroma and smoke in the virtual domain.

FIG. 22 shows an example of a system which may be installed at multiple facilities, in this case two facilities which may be at geographically separate locations. The system of FIG. 22 comprises two instances of the system shown in FIG. 20 which may be installed at respective facilities, for example separate buildings, as described elsewhere here. A computing device, in this example a tablet, indicated as an iPad, is provided at each facility along with a larger display device such as a TV screen. However in this example instead of a server and decision engine being provided for each facility, the facilities share a common server 2020 and decision engine 2025, which may be located at one of the facilities. In this system sensor data may be reported from any of the sensors at any of the facilities and, based on rules implemented in the decision engine 2025, one or more events may be caused in response to the sensor information via any of the actuators. In a multiple facility system as shown in FIG. 22 each facility is shown to have sensors and actuators with associated devices for a subject, which in practice may be multiplied for multiple subjects, domain and virtual environment. Any one of the facilities may be provided with a reduced set of the components shown in FIG. 22. For example a facility may be virtual-only or physical only.

In the described embodiments of the invention the system may be implemented using any form of a computing and/or electronic system as noted elsewhere herein. Such a device may comprise one or more processors which may be microprocessors, controllers or any other suitable type of processors for processing computer executable instructions to control the operation of the device in order to gather and record routing information. In some examples, for example where a system on a chip architecture is used, the processors may include one or more fixed function blocks (also referred to as accelerators) which implement a part of the method in hardware (rather than software or firmware). Platform software comprising an operating system or any other suitable platform software may be provided at the computing-based device to enable application software to be executed on the device.

The term “computing system” or computing device is used herein to refer to any device with processing capability such that it can execute instructions. Those skilled in the art will realise that such processing capabilities may be incorporated into many different devices and therefore the term “computing system” includes PCs, servers, smart mobile telephones, personal digital assistants and many other devices.

It will be understood that the benefits and advantages described above may relate to one embodiment or may relate to several embodiments. The embodiments are not limited to those that solve any or all of the stated problems or those that have any or all of the stated benefits and advantages.

There is disclosed in the foregoing systems as described in the following numbered clauses:
1. A system for monitoring the behaviour of a human or animal subject, the system comprising: a plurality of subject sensors for monitoring the subject's behaviour including one or more body worn or carried sensors;
   a subject device to be worn by the subject and to receive sensor data from the subject sensors.
2. The system of clause 1 wherein the subject sensors comprise one or more of:
   eye movement sensors;
   biometric sensors; and
   position sensors.
3. The system of clause 1 or clause 2 wherein the subject sensors comprise one or more sensors on equipment carried by a subject, for example on a weapon.
4. The system of any preceding clause wherein the subject sensors comprise one or more remote sensors configured to sense one or more behaviours of the subject.
5. The system of any preceding clause wherein the subject device comprises a personal situation monitoring device configured also to function to inform the subject about a current situation.
6. The system of any preceding clause further comprising a server arranged to receive sensor data from the subject device and to transmit instructions based on the subject sensor data.
7. The system of clause 6 further comprising a domain device to be located in the domain and to receive instructions from the server.
8. The system clause 7 further comprising a plurality of domain actuators for causing one or more events in the domain in response to instructions from the domain device.
9. The system of any preceding clause further comprising a plurality of domain sensors arranged to detect one or more events in the domain, wherein the server is arranged to receive sensor data from the domain sensors and to transmit instructions based on the domain sensor data; and
   a plurality of subject actuators for causing one or more events at the subject in response to instructions from the server.
10. The system of any preceding clause wherein the subject device is configured to communicate directly with at least one of the plurality of subject actuators to transmit instructions based on the subject sensor data.
11. The system of any preceding clause 1 wherein the domain device is configured to communicate directly with the domain actuators to transmit instructions based on the domain sensor data.
12. The system of clause 10 or clause 11 configured to implement a set of rules for causing events based on sensor data, wherein one or both of the subject device and the domain device are configured to implement at least one of the rules independently of the server.
13. The system of clause 12 wherein one or both of the subject device and the domain device are configured to process sensor data to determine whether to cause an event or to transmit the data to the server for the server to determine whether to cause an event.
14. The system of clause 13 in which the rules prioritise certain events according to certain sensor data or combinations of sensor data, and the determination is according to the priority of the required event.
15. The system of any preceding clause configured for the subject to be outside the domain.
16. The system of any preceding clause configured to provide a subject with a simulated view of an area in which the domain is apparently situated.
17. The system of any preceding configured to provide a subject with a simulated view of the domain from a perspective not available to the subject.
18. The system of clause 16 or clause 17 in which the simulated view includes the subject.
19. The system of clause 16 in which the simulated view is provided via the subject device.
20. The system of any preceding clause wherein one or both of the subject device and the domain device is configured to timestamp data from one or more of the body worn and remote sensors.
21. The system of any preceding clause wherein one or both of the subject device and the domain device is configured to record sensor data from multiple sensors, wherein data is received from different sensors at different rates and the device is configured to record different proportions of data from different sensors.
22. The system of clause 20 wherein one or both of the subject and device sensors is configured to record sensor data according to the level of confidence in the data accuracy.
23. The system of clause 21 or clause 22 wherein one or both of the subject and device sensors is configured to determine the level of accuracy of data from one sensor based on data from another sensor.
24. The system of any preceding clause wherein the domain device is configured to determine whether an instruction from the server to cause an event has already been implemented,
25. The system of any preceding clause wherein the domain device is configured to receive an instruction from the server to cause an event and to determine before implementing the instruction whether the timing of the instructed event is suitable having regard to the progress of events or received sensor data.
26. The system of any preceding clause comprising multiple subject devices to be worn by respective subjects and multiple domain devices to be located in different domains.
27. The system of clause 26 wherein the multiple subject and domain devices are configured to communicate with each other via the same server.
28. The system of clause 26 or 27 configured such that an event in one domain may be caused based on subject sensor data from a subject device in a different domain.
29. The system of clause 26, 27 or 28 configured for the domains to be geographically separate.
30. The system of clause 29 configured for geographically separate domains to behave as relatively proximate areas.
31. The system of clause 29 or clause 30 configured to simulate any one or more of the relative proximity, relative height and relative orientation of different domains to be different from any of their actual relative proximity, relative height and relative orientation.
32. The system of any of clauses 26 to 31 configured so that the multiple domains represent non-overlapping spaces in a synthetic larger space.
33. A system allowing virtual and real events to take place contemporaneously and to influence each other, the system comprising:
   apparatus for providing a virtual environment to a real individual;
   one or more sensors for sensing activity by a real individual in a real environment; and
   simulation apparatus for simulating events for an individual in a real environment using physical effects;
   the system being configured such that:
   an action by a real individual in the virtual environment causes the simulation of an event in real time for another real individual in a real environment, by the simulation apparatus;
   an action by a real individual in the real environment causes the simulation of an event in real time in the virtual environment for the other real individual;
   wherein the simulation apparatus for simulating events for an individual in a real environment comprises a system according to any preceding clause.
34. The system of any preceding clause wherein the subject sensors comprise any one or more of: eye movement tracking, biometric sensors, sensors provided on subject equipment, position sensing, cameras and other surveillance devices, microphones, handheld controllers, player identifiers, treadmills and other sensors capable of sensing subject activity or behaviour.
35. The system of any preceding clause comprising domain sensors comprising any one or more of: cameras, sensors to detect movement of doors and other moveables, targets, location beacons, human adversaries provided with sensing equipment, temperature sensors.
36. The system of any preceding clause comprising subject actuators comprising any one or more of: speakers e.g. in earpieces, haptic feedback devices, heads-up displays.
37. The system of any preceding clause comprising domain actuators comprising any one or more of: lighting, speakers, smoke generators, aroma generators, reactive targets, vibration devices such as rumble flooring, heating, air conditioning.
38. A system allowing virtual and real events to take place contemporaneously and to influence each other, the system comprising:
apparatus for providing a virtual environment to a real individual;
one or more sensors for sensing activity by a real individual in a real environment; and
simulation apparatus for simulating events for an individual in a real environment using physical effects;
the system being configured such that:
an action by a real individual in the virtual environment causes the simulation of an event in real time for another real individual in a real environment, by the simulation apparatus;
an action by a real individual in the real environment causes the simulation of an event in real time in the virtual environment for the other real individual.
39. The system of clause 38 configured such that the real and the virtual environments are separated from each other so that it is not possible for real interactions between the real individuals to take place.
40. The system of clause 38 or clause 39 configured such that the real and virtual environments represent physical spaces that do not overlap.
41. The system of clause 38, 39 or 40 wherein the apparatus for providing a virtual environment comprises a virtual reality headset and the real environment is visible to a user with naked eyes.
42. The system of clauses 38 to 41 configured to provide to an individual in the real environment a view of an area apparently outside the real environment in which the individual in the real environment is able to move.
43. The system of clause 42 configured such that the area apparently outside the real environment at least partially comprises the virtual environment.
44. The system of clause 43 configured such that a real individual in the real environment and a real individual in the virtual environment are invisible to each other or one is invisible to the other but not vice versa.
45. The system of any of clauses 38 to 44 comprising weaponry for use by a real individual in the virtual environment.
46. The system of any of clauses 38 to 45 comprising one or more physical targets for use in the real environment to represent one or more individuals in respective virtual environments.
47. The system of any of clauses 38 to 46 comprising a visual display for use by a real individual in the real environment, the system being configured to provide a simulated aerial view of one or both of the real and virtual environments.
48. The system of clause 47 configured such that one or more predetermined actions by a real individual in the virtual environment are simulated to an individual in the real environment via the visual display.
49. The system of clause 47 or 48 in which the one or more predetermined actions are also simulated to the real individual using an audio effect via one or more speakers in the real environment.
50. The system of clause 48, 49 or 50 configured for a real individual to control the visual display in the manner of controlling an aerial vehicle to determine the area displayed.
51. The system of clause 50 configured to simulate the aerial vehicle being weaponised and operable via a device including the visual display.
52. The system of any of clauses 38 to 51 configured for different real individuals to act in different geographically separated real environments in which the different real environments are inserted into a virtual space in which the distance between and/or relative orientation of the real environments is different from the real distance and/or relative orientation.
53. The system of any of clauses 38 to 52 configured to simulate for a real individual in the real environment a view of the virtual environment.
54. The system of any of clauses 38 to 53 configured to enable a real individual to cross from a real environment representing a first area into a real environment representing a second area which the subject has viewed in the virtual environment.
55. The system of any of clauses 38 to 54 configured for real immovable objects in the real environment such as targets described further below may be represented as movable objects in the virtual environment.
56. The system of clause 55 wherein the real environment includes one or more items in a fixed location that is represented by a movable item in the virtual environment and which is moved to the fixed location in the virtual environment as a subject viewing the virtual environment moves into the real environment.
57. The system of any of clauses 38 to 56 configured for use by multiple users in one or both of virtual and real environments.
58. The system of clause 57 comprising apparatus for providing multiple virtual environments to respective real individuals;
the system being configured such that:
an action by any one of the real individuals in the virtual environments causes the simulation of an event in real time for another real individual in the real environment, by the simulation apparatus.
59. The system of clause 58 configured such that an action by a real individual in the real environment causes the simulation of an event in real time for more multiple real individuals in respective virtual environments.
60. The system of clause 57, 58 or 59 comprising simulation apparatus for simulating events for real individuals in respective real environments using physical effects.
61. The system of any of clauses 38 to 60 wherein the simulation apparatus for simulating events for an individual in a real environment comprises a plurality of subject sensors for monitoring the subject's behaviour including one or more body worn or carried sensors and one or more remote sensors;
a subject device to be worn by the subject and to receive sensor data from the body worn sensors and from the remote sensors;
a server arranged to receive sensor data from the subject device and to transmit instructions based on the subject sensor data;
a domain device to be located in the domain and to receive instructions from the server; and
a plurality of domain actuators for causing one or more events in the domain in response to instructions from the domain device.
62. A system for simulating an environment to one or more individuals, the system comprising: simulation apparatus for simulating events for the one or more individuals in a real domain using physical effects;
wherein the system is configured to provide to the one or more individuals a synthesised view of or from area or space apparently outside the domain.
63. The system of any of clauses 38 to 62 configured to provide to the one or more individuals a simulated view of the domain from a perspective not available to the one or more individuals.
64. The system of clause 38 to 63 wherein the simulated view includes a simulated image of the one or more individuals.
65. The system of any of clauses 38 to 64 wherein the simulated view is provided via a device that may be worn by an individual.
66. The system of clause 65 wherein the simulated view is in the form of an aerial vehicle feed and the device is configured to enable the individual to control the area displayed in the manner of controlling an aerial vehicle.

It will be understood that the above description of a preferred embodiment is given by way of example only and that various modifications may be made by those skilled in the art. What has been described above includes examples of one or more embodiments. It is, of course, not possible to describe every conceivable modification and alteration of the above devices or methods for purposes of describing the aforementioned aspects, but one of ordinary skill in the art can recognize that many further modifications and permutations of various aspects are possible. Accordingly, the described aspects are intended to embrace all such alterations, modifications, and variations that fall within the scope of the appended claims.

1. A system allowing virtual and real events to take place contemporaneously and to influence each other, the system comprising:
apparatus for providing a virtual environment to a real individual;
one or more sensors for sensing activity by a real individual in a real environment; and
a simulation apparatus for simulating events for an individual in a real environment using physical effects;
the system being configured such that:
an action by a real individual in the virtual environment causes the simulation of an event in real time for another real individual in a real environment, by the simulation apparatus; and
an action by a real individual in the real environment causes the simulation of an event in real time in the virtual environment for the other real individual.

2. The system of claim 1 configured such that the real and the virtual environments are separated from each other so that it is not possible for real interactions between the real individuals to take place.

3. (canceled)

4. The system of claim 1 wherein the apparatus for providing a virtual environment comprises a virtual reality headset and the real environment is visible to a user with naked eyes.

5. The system of claim 1 configured to provide to an individual in the real environment a view of an area apparently outside the real environment in which the individual in the real environment is able to move.

6. The system of claim 5 configured such that the area apparently outside the real environment at least partially comprises the virtual environment.

7. The system of claim 6 configured such that a real individual in the real environment and a real individual in the virtual environment are invisible to each other or one is invisible to the other but not vice versa.

8. (canceled)

9. The system of claim 1 comprising one or more physical targets for use in the real environment to represent one or more individuals in respective virtual environments.

10. The system of claim 1 comprising a visual display for use by a real individual in the real environment, the system being configured to provide a simulated aerial view of one or both of the real and virtual environments.

11. The system of claim 10 configured such that one or more predetermined actions by a real individual in the virtual environment are simulated to an individual in the real environment via the visual display.

12. (canceled)

13. The system of claim 10 configured for a real individual to control the visual display in the manner of controlling an aerial vehicle to determine the area displayed.

14. (canceled)

15. The system of claim 1 configured for different real individuals to act in different geographically separated real environments in which the different real environments are inserted into a virtual space in which the distance between and/or relative orientation of the real environments is different from the real distance and/or relative orientation.

16. (canceled)

17. The system of claim 1 configured to enable a real individual to cross from a real environment representing a first area into a real environment representing a second area which the subject has viewed in the virtual environment.

18. (canceled)

19. The system of claim 1 wherein the real environment includes one or more items in a fixed location that is represented by a movable item in the virtual environment and which is moved to the fixed location in the virtual environment as a subject viewing the virtual environment moves into the real environment.

20. The system of claim 1 configured for use by multiple users in one or both of virtual and real environments.

21. The system of claim 20 comprising apparatus for providing multiple virtual environments to respective real individuals;
the system being configured such that:
an action by any one of the real individuals in the virtual environments causes the simulation of an event in real time for another real individual in the real environment, by the simulation apparatus.

22-23. (canceled)

24. A system for allowing virtual and real events to take place contemporaneously and to influence each other, the system comprising:
a simulation apparatus for simulating events for an individual in a real environment comprising a plurality of subject sensors for monitoring the subject's behaviour including one or more body worn or carried sensors and one or more remote sensors;
a subject device to be worn by the subject and to receive sensor data from the body worn sensors and from the remote sensors;
a server arranged to receive sensor data from the subject device and to transmit instructions based on the subject sensor data;
a domain device to be located in the domain and to receive instructions from the server; and
a plurality of domain actuators for causing one or more events in the domain in response to instructions from the domain device.

25. A system for simulating an environment to one or more individuals, the system comprising:
simulation apparatus for simulating events for the one or more individuals in a real domain using physical effects;
wherein the system is configured to provide to the one or more individuals a synthesized view of or from area or space apparently outside the domain.

26. The system of claim 25 configured to provide to the one or more individuals a simulated view of the domain from a perspective not available to the one or more individuals.

27. The system of claim 26 wherein the simulated view includes a simulated image of the one or more individuals.

28. (canceled)

29. The system of claim 28 wherein the simulated view is in the form of an aerial vehicle feed and the device is configured to enable the individual to control the area displayed in the manner of controlling an aerial vehicle.
